(19) United States
(12) Patent Application Publication
(10) Pub. No.: US 2026/0141930 A1
(43) Pub. Date: May 21, 2026

(54) SEMICONDUCTOR MEMORY DEVICE

(71) Applicant: Samsung Electronics Co., Ltd., Suwon-si (KR)

(72) Inventor: Jeon Il LEE, Suwon-si (KR)

(21) Appl. No.: 19/385,760

(22) Filed: Nov. 11, 2025

(30) Foreign Application Priority Data
Nov. 21, 2024 (KR) 10-2024-0167805

(51) Int. Cl. G11C 5/06; G11C 11/4091; H01L 25/18; H10B 12/00; H10D 80/30

(52) U.S. Cl. CPC G11C 5/063; G11C 11/4091; H10B 12/09; H10B 12/315; H10B 12/482; H10B 12/488; H10B 12/50; H10D 80/30; H10W 90/00

(57) ABSTRACT

A semiconductor memory device includes word lines spaced apart from each other in a vertical direction and extending in a first horizontal direction; first local bit lines and second local bit lines intersecting the word lines and extending in the vertical direction; first global bit lines electrically connected to the first local bit lines, below the word lines; and second global bit lines electrically connected to the second local bit lines, above the word lines.

### CROSS-REFERENCE TO RELATED APPLICATION

This application claims priority to Korean Patent Application No. 10-2024-0167805 filed on Nov. 21, 2024 in the Korean Intellectual Property Office, the contents of which in its entirety are herein incorporated by reference.

### BACKGROUND

### 1. Technical Field

The present disclosure relates to a semiconductor memory device, and more particularly, to a three-dimensional semiconductor memory device with improved electrical characteristics.

### 2. Description of the Related Art

In order to satisfy the excellent performance and low price of semiconductor devices demanded by consumers, the degree of integration of the semiconductor devices continues to increase. Since the degree of integration of the semiconductor devices is an important factor determining the price of semiconductor-related products, the increased degree of integration is particularly important.

Since the degree of integration of conventional two-dimensional or planar semiconductor devices is mainly determined by an area occupied by unit memory cells, it is greatly affected by a level of technology for forming fine patterns. However, since ultra-expensive equipment is typically required to form the fine patterns, the degree of integration of the two-dimensional semiconductor devices is increasing, but is still limited. Accordingly, three-dimensional semiconductor memory devices including memory cells that are three-dimensionally arranged being proposed.

### SUMMARY

Aspects of the present disclosure provide a semiconductor memory device capable of having improved product reliability.

According to an aspect of the disclosure, a semiconductor memory device includes a three-dimensional memory cell array including memory cells including cell transistors arranged in a three-dimensional array and corresponding data storage elements arranged in a three-dimensional array; a plurality of word lines extending lengthwise in a first horizontal direction, and spaced apart from each other in a vertical direction and a second horizontal direction crossing the first horizontal direction; each cell transistor including a semiconductor pattern extending lengthwise in the second horizontal direction and having a first end connected to a respective data storage element, each semiconductor pattern intersecting a word line of the plurality of word lines; first local bit lines crossing the word lines and second local bit lines crossing the word lines, each bit line of the first local bit lines and second local bit lines extending lengthwise in the vertical direction; first global bit lines extending lengthwise in the second horizontal direction and electrically connected to the first local bit lines, below the word lines; and second global bit lines extending lengthwise in the second horizontal direction and electrically connected to the second local bit lines, above the word lines.

According to an aspect of the disclosure, a semiconductor memory device includes word lines spaced apart from each other in a vertical direction and extending lengthwise in a first horizontal direction; first local bit lines and second local bit lines crossing the word lines and extending lengthwise in the vertical direction; first global bit lines electrically connected to the first local bit lines, below the word lines; and second global bit lines electrically connected to the second local bit lines, above the word lines.

According to an aspect of the disclosure, a semiconductor memory device includes a first peripheral circuit structure including a first semiconductor layer and first transistors of the first semiconductor layer; a memory cell structure on the first peripheral circuit structure and including word lines extending lengthwise in a first horizontal direction and spaced apart from each other in a vertical direction and bit lines extending lengthwise in the vertical direction and spaced apart from each other in the first horizontal direction; and a second peripheral circuit structure on the memory cell structure so that the memory cell structure is between the first peripheral circuit structure and the second peripheral circuit structure, the second peripheral circuit structure including a second semiconductor layer and second transistors of the second semiconductor layer. The bit lines include first local bit lines and second local bit lines, the first local bit lines are electrically connected to the first transistors, and the second local bit lines are electrically connected to the second transistors.

According to an aspect of the disclosure, a semiconductor memory device includes a first peripheral circuit structure including a first semiconductor layer, first operational transistors on the first semiconductor layer, and a first conductive pattern electrically connected to the first operational transistors; a cell structure on the first peripheral circuit structure and including word lines extending lengthwise in a first horizontal direction and spaced apart from each other in a vertical direction, first and second local bit lines extending lengthwise in the vertical direction and spaced apart from each other in the first horizontal direction, first global bit lines below the word lines, and second global bit lines above the word lines; and a second peripheral circuit structure on the cell structure so that the cell structure is between the first peripheral circuit structure and the second peripheral circuit structure, the second peripheral circuit structure including a second semiconductor layer, second operational transistors on the second semiconductor layer, and a second conductive pattern electrically connected to the second operational transistors. The first local bit lines and the second local bit lines are disposed alternately along the first horizontal direction, the first local bit lines are electrically connected to the first operational transistors through the first global bit lines and the first conductive pattern, and the second local bit lines are electrically connected to the second operational transistors through the second global bit lines and the second conductive pattern.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram of a semiconductor memory device according to some exemplary embodiments;

FIG. 2 is an exemplary circuit diagram illustrating a memory cell array of the semiconductor memory device according to some exemplary embodiments;

FIG. 3 is a view for describing the semiconductor memory device according to some exemplary embodiments;

FIGS. 4 and 5 are plan views for describing the semiconductor memory device according to some exemplary embodiments;

FIG. 6 is a cross-sectional view taken along line A-A of FIGS. 4 and 5;

FIG. 7 is a cross-sectional view taken along line B-B′ of FIGS. 4 and 5;

FIG. 8 is a cross-sectional view taken along line C-C′ of FIGS. 4 and 5;

FIG. 9 is a cross-sectional view taken along line D-D′ of FIGS. 4 and 5;

FIGS. 10 to 12 are views for describing a semiconductor memory device according to some exemplary embodiments;

FIGS. 13 to 15 are views for describing a semiconductor memory device according to some exemplary embodiments;

FIGS. 16 and 17 are views for describing a semiconductor memory device according to some exemplary embodiments; and

FIGS. 18 to 29 are views for describing a method for manufacturing a semiconductor memory device according to some exemplary embodiments.

### DETAILED DESCRIPTION OF THE EMBODIMENTS

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, connection vias, etc. As such, directly electrically connected components do not include components electrically connected through active elements, such as transistors or diodes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features and vice versa. Thus, the term “below” taken with no reference point or direction can encompass both an orientation of above and below. The device may be otherwise oriented (rotated 90 degrees or at other orientations) and the spatially relative descriptors used herein interpreted accordingly.

An item, layer, or portion of an item or layer described as extending “lengthwise” in a particular direction has a length in the particular direction and a width perpendicular to that direction, where the length is greater than the width.

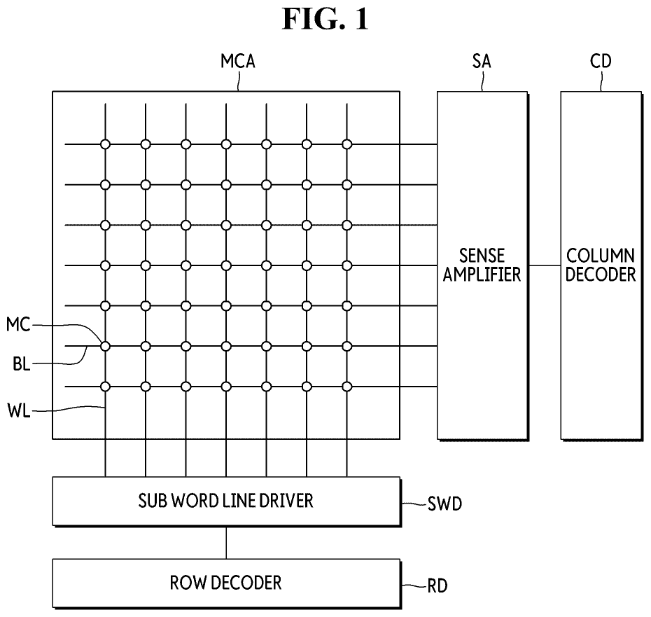

FIG. 1 is a block diagram of a semiconductor memory device according to some exemplary embodiments.

Referring to FIG. 1, a semiconductor memory device according to some exemplary embodiments may include a memory cell array MCA, a row decoder RD, a sense amplifier SA, and a column decoder CD.

The memory cell array MCA may include a plurality of memory cells MC arranged three-dimensionally. The memory cells MC may be connected between word lines WL and bit lines BL that cross each other.

The row decoder RD may decode an address that is input from the outside and select any one of the word lines WL of the memory cell array MCA. The address decoded by the row decoder RD may be provided to a sub word line driver SWD.

The sub word line driver SWD may provide a predetermined voltage to each of the selected word line WL and unselected word lines WL in response to the control of control circuits.

The sense amplifier SA may sense and amplify a voltage difference between a selected bit line BL and a reference bit line according to the address decoded from the column decoder CD, and output the sensed and amplified voltage difference.

The column decoder CD may provide a data transmission path between the sense amplifier SA and an external device (e.g., a memory controller). The column decoder CD may decode an address that is input from the outside and select any one of the bit lines BL.

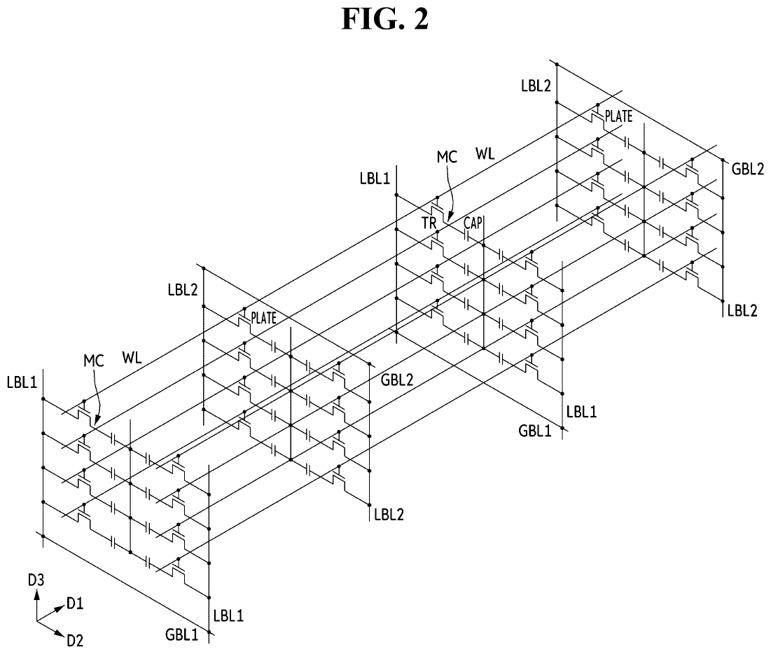

FIG. 2 is an exemplary circuit diagram illustrating a memory cell array of the semiconductor memory device according to some exemplary embodiments.

Referring to FIGS. 1 and 2, in the semiconductor memory device according to some exemplary embodiments, the memory cell MC may include a cell transistor TR and a data storage element CAP. The cell transistor TR and the data storage element CAP may be electrically connected in series with each other. The memory cell MC may be, for example, DRAM.

The bit lines BL may be conductive patterns (e.g., metallic conductive lines) extending in a vertical direction D3. The bit lines BL may be spaced apart from each other along a first horizontal direction D1 and a second horizontal direction D2. The first horizontal direction D1 and the second horizontal direction D2 may intersect each other and may be perpendicular to each other.

The first horizontal direction D1, the second horizontal direction D2, and the vertical direction D3 may intersect each other. Hereinafter, lower and upper portions and lower and upper surfaces are defined based on the vertical direction D3.

The bit lines BL may include first local bit lines LBL1, second local bit lines LBL2, first global bit lines GBL1, and second global bit lines GBL2. The first local bit lines LBL1 may be spaced apart from each other along the second horizontal direction D2. The second local bit lines LBL2 may be spaced apart from each other along the second horizontal direction D2. The first local bit line LBL1 and the second local bit line LBL2 may be alternately disposed along the first horizontal direction D1.

The first global bit line GBL1 and the second global bit line GBL2 may each be conductive patterns (e.g., metallic conductive lines) extending in the second horizontal direction D2. Some of the bit lines BL are connected to each other by the first global bit lines GBL1, and the remainder are connected to each other by the second global bit lines GBL2. The first local bit lines LBL1 spaced apart from each other along the second horizontal direction D2 are connected to each other by the first global bit line GBL1. The second local bit lines LBL2 spaced apart from each other along the second horizontal direction D2 are connected to each other by the second global bit line GBL2. The first global bit line GBL1 and the second global bit line GBL2 may be alternately disposed along the first horizontal direction D1.

For example, the second horizontal direction D2 may be defined as a row direction, the first horizontal direction D1 may be defined as a column direction, the first local bit lines LBL1 may be disposed in odd-numbered rows, and the second local bit lines LBL2 may be disposed in even-numbered rows. The first global bit lines GBL1 may connect the first local bit lines LBL1 disposed in the odd-numbered rows to each other, and the second global bit lines GBL2 may connect the second local bit lines LBL2 disposed in the even-numbered rows to each other.

The word lines WL may be conductive patterns (e.g., metallic conductive lines) extending in the first horizontal direction D1. The word lines WL may be spaced apart from each other along the second horizontal direction D2 and the vertical direction D3.

The data storage element CAP may be commonly connected to a plate electrode PLATE extending in the first horizontal direction D1 and the vertical direction D3. In some exemplary embodiments, the plate electrodes PLATE arranged along the first horizontal direction D1 may be integrally formed.

The data storage element CAP and the cell transistor TR arranged along the second horizontal direction D2 may be symmetrically disposed based on a plane extending in the first horizontal direction D1 and the vertical direction D3 in which the plate electrode PLATE is disposed.

A gate of the cell transistor TR may be connected to the word line WL, a first source/drain of the cell transistor TR may be connected to the data storage element CAP, and a second source/drain of the cell transistor TR may be connected to the bit line BL. The data storage element CAP may be a capacitor or a variable resistor, etc. In the following, an example in which the data storage element CAP is a capacitor will be described. The first source/drain of the cell transistor TR may be connected to a storage electrode of the capacitor.

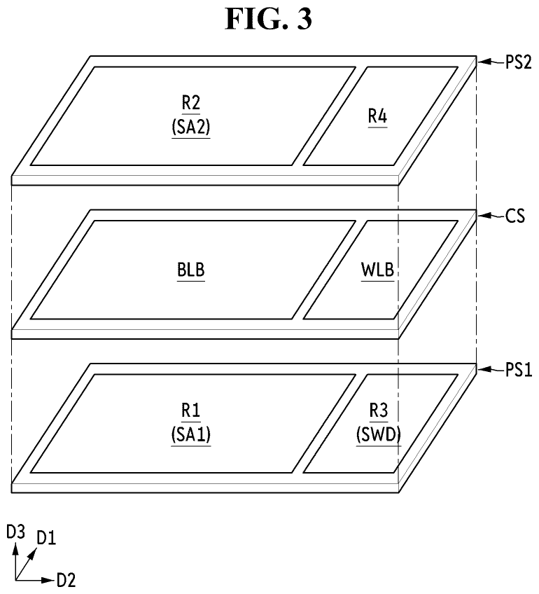

FIG. 3 is a view for describing the semiconductor memory device according to some exemplary embodiments.

Referring to FIGS. 1 to 3, the semiconductor memory device according to some exemplary embodiments may include a cell structure CS, a first peripheral circuit structure PS1, and a second peripheral circuit structure PS2. The cell structure CS may be disposed between the first peripheral circuit structure PS1 and the second peripheral circuit structure PS2. The first peripheral circuit structure PS1 may be disposed below the cell structure CS, and the second peripheral circuit structure PS2 may be disposed above the cell structure CS.

The memory cell array MCA including the memory cells MC that are three-dimensionally arranged may be provided in the cell structure CS. The cell structure CS may include a bit line connection region BLB and a word line connection region WLB.

The first peripheral circuit structure PS1 may include a first region R1 and a third region R3. The second peripheral circuit structure PS2 may include a second region R2 and a fourth region R4. The first region R1 and the second region R2 may overlap the bit line connection region BLB in the vertical direction D3. The third region R3 and the fourth region R4 may overlap the word line connection region WLB in the vertical direction D3.

A portion of the sense amplifier SA of FIG. 1, i.e., the first sense amplifier SA1, may be provided in the first region R1, and the remainder, i.e., the second sense amplifier SA2, may be provided in the second region R2. The sub word line driver SWD of FIG. 1 may be provided in the third region R3. A control signal generation circuit for controlling the first and second sense amplifiers SA1 and SA2 and a control signal generation circuit for controlling the sub word line driver SWD may be provided in the fourth region R4. In addition, a voltage generator providing operating voltages to the first and second sense amplifiers SA1 and SA2 and the sub word line driver SWD may be provided in the fourth region R4.

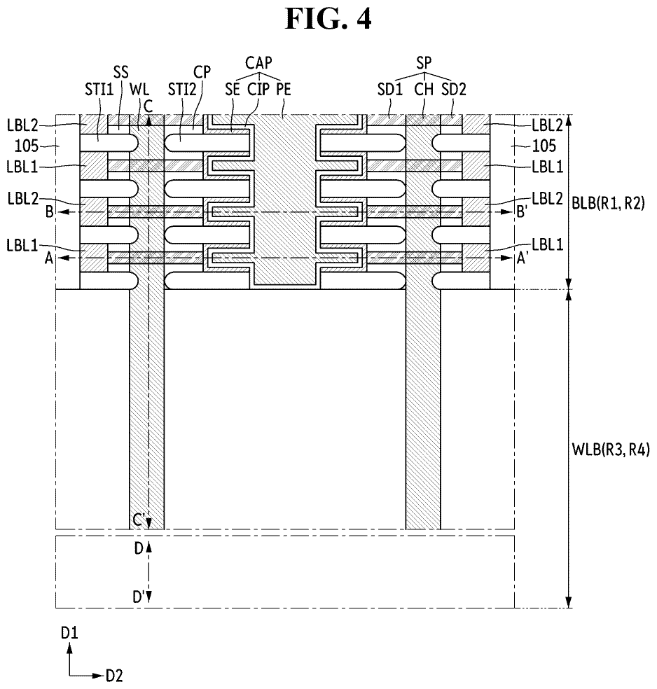

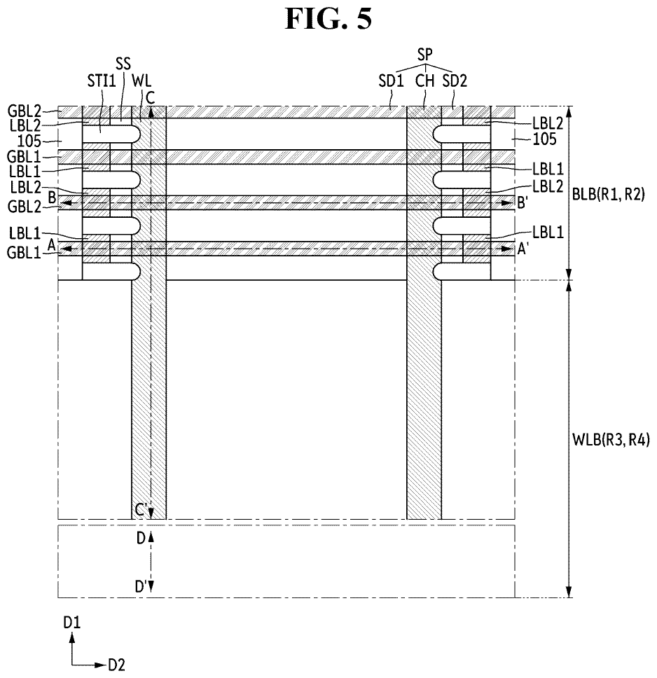

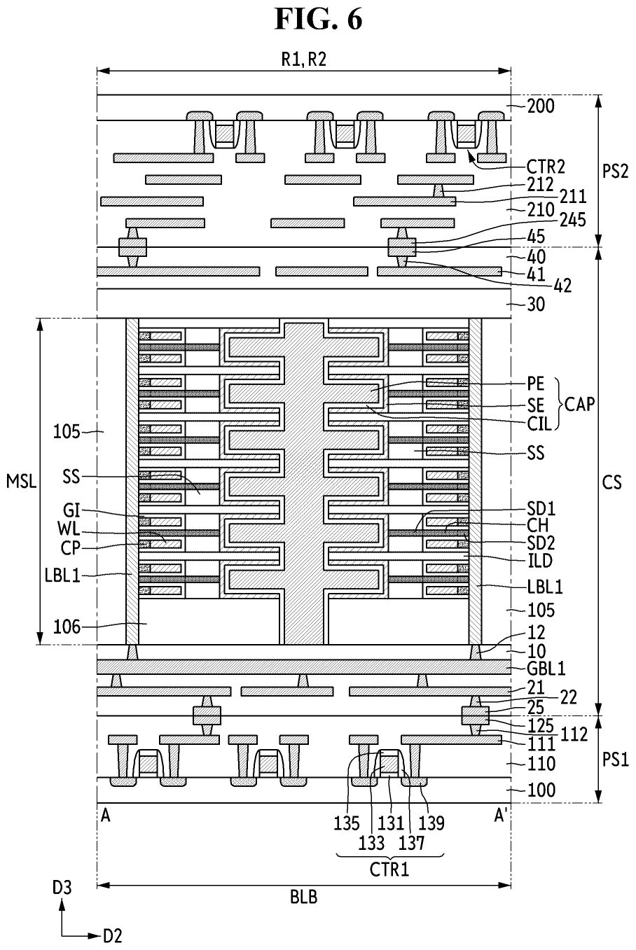

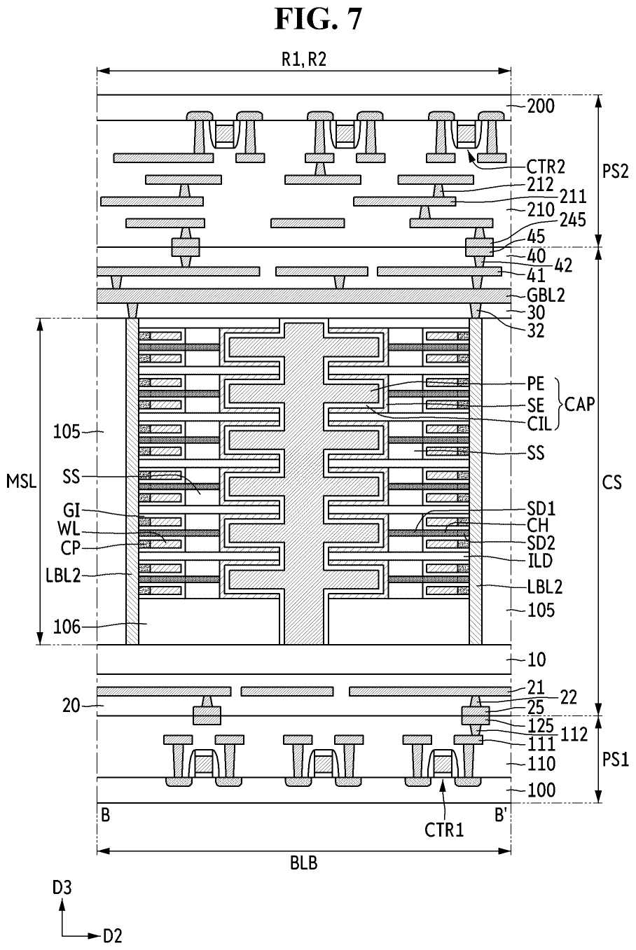

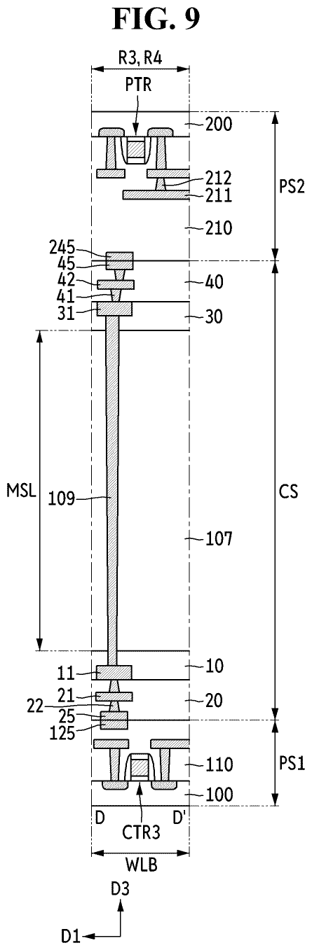

FIGS. 4 and 5 are plan views for describing the semiconductor memory device according to some exemplary embodiments. FIG. 6 is a cross-sectional view taken along line A-A of FIGS. 4 and 5, FIG. 7 is a cross-sectional view taken along line B-B′ of FIGS. 4 and 5, FIG. 8 is a cross-sectional view taken along line C-C′ of FIGS. 4 and 5, and FIG. 9 is a cross-sectional view taken along line D-D′ of FIGS. 4 and 5. In FIG. 4, the first global bit lines GBL1 and the second global bit lines GBL2 are omitted, and in FIG. 5, the second separation insulating pattern STI2, the capping insulating pattern CP, and the data storage element CAP are omitted.

Referring to FIGS. 4 to 9 in the semiconductor memory device according to some exemplary embodiments, the cell structure CS may include a memory cell layer MSL, first and second lower insulating layers 10 and 20, a first bit line contact 12, a first global bit line GBL1, lower conductive patterns 21 and 22, first and second upper insulating layers 30 and 40, a second bit line contact 32, a second global bit line GBL2, and upper conductive patterns 41 and 42.

The memory cell layer MSL may include interlayer insulating patterns ILD, semiconductor patterns SP, word lines WL, a gate insulating film GI, a capping insulating pattern CP, a spacer insulating pattern SS, first and second separation insulating patterns STI1 and STI2, a buried insulating pattern 105, a data storage element CAP, and first and second cell insulating layers 106 and 107.

The interlayer insulating patterns ILD may be stacked in the vertical direction D3. The interlayer insulating patterns ILD may be spaced apart from each other in the vertical direction D3.

The interlayer insulating pattern ILD may include an insulating material. The interlayer insulating pattern ILD may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the interlayer insulating pattern ILD may be a silicon oxide film.

The semiconductor patterns SP may be stacked in the vertical direction D3. The semiconductor patterns SP may be spaced apart from each other in the vertical direction D3. The semiconductor pattern SP may be disposed between the interlayer insulating patterns ILD adjacent to each other in the vertical direction D3. The interlayer insulating pattern ILD may be disposed between the semiconductor patterns SP adjacent to each other in the vertical direction D3.

The semiconductor pattern SP may extend in the second horizontal direction D2. The semiconductor patterns SP positioned at the same height may be spaced apart from each other in the first horizontal direction D1. The interlayer insulating pattern ILD may protrude further in the second horizontal direction D2 than the semiconductor pattern SP.

The semiconductor pattern SP may include at least one of a single crystal semiconductor, a polycrystalline semiconductor, an oxide semiconductor, and a two-dimensional material. For example, the single crystal semiconductor may be single crystal silicon. For example, the polycrystalline semiconductor may be polysilicon. For example, the oxide semiconductor may be selected from a group consisting of IGZO(InGaZnO), Sn-IGZO, IWO(InWO), IZO(InZnO), ZTO(ZnSnO), ZnO, YZO(yttrium-doped zinc oxide), IGSO(InGaSiO), InO, SnO, TiO, ZnON, MgZnO, ZrInZnO, HfInZnO, SnInZnO, AlSnInZnO, SiInZnO, AlZnSnO, GaZnSnO, and ZrZnSnO, but is not limited thereto. For example, the two-dimensional semiconductor may be made of a transition metal dichalcogenide, or a bipolar semiconductor material that utilizes both electrons and holes as driving charges. For example, the two-dimensional semiconductor may be selected from a group consisting of MoS₂, MoSe₂, WS₂, NbS₂, TaS₂, ZrS₂, HfS₂, TcS₂, ReS₂, CuS₂, GaS₂, InS₂, SnS₂, GeS₂, PbS₂, WSe₂, NbSe₂, TaSe₂, ZrSe₂, HfSe₂, TcSe₂, ReSe₂, CuSe₂, GaSe₂, InSe₂, SnSe₂, GeSe₂, PbSe₂, MoTe₂, WTe₂, NbTe₂, TaTe₂, ZrTe₂, HfTe₂, TcTe₂, ReTe₂, CuTe₂, GaTe₂, InTe₂, SnTe₂, GeTe₂, and PbTe₂, but is not limited thereto.

The semiconductor pattern SP may include a channel region CH, a first impurity region SD1, and a second impurity region SD2. The channel region CH may be interposed between the first and second impurity regions SD1 and SD2. The channel region CH may correspond to the channel of the cell transistor TR described with reference to FIG. 2. The first and second impurity regions SD1 and SD2 may correspond to the first source/drain and the second source/drain of the cell transistor TR described with reference to FIG. 2, respectively.

The first and second impurity regions SD1 and SD2 may be regions in which the semiconductor pattern SP is doped with impurities. Accordingly, the first and second impurity regions SD1 and SD2 may have either n-type or p-type conductivity. The first impurity region SD1 may be formed at a first end of the semiconductor pattern SP, and the second impurity region SD2 may be formed at a second end of the semiconductor pattern SP. The second end may be opposed to the first end in the second horizontal direction D2.

The first impurity region SD1 may be connected to the data storage element CAP. The first impurity region SD1 may be connected to the storage electrode SE. The second impurity region SD2 may be connected to the first and second local bit lines LBL1 and LBL2.

The first and second local bit lines LBL1 and LBL2 may be disposed on the bit line connection region BLB. The first and second local bit lines LBL1 and LBL2 may be disposed on the semiconductor patterns SP and the interlayer insulating patterns ILD. The first and second local bit lines LBL1 and LBL2 may each be connected to the semiconductor patterns SP spaced apart from each other in the vertical direction D3.

The first and second local bit lines LBL1 and LBL2 may each include a conductive material, for example, at least one of a doped semiconductor material (doped silicon, doped silicon-germanium, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide, etc.), but are not limited thereto.

The word lines WL may be stacked in the vertical direction D3. The word lines WL may be spaced apart from each other in the vertical direction D3. The word line WL may be disposed on at least a portion of an outer circumferential surface of the channel region CH of the semiconductor pattern SP. The word line WL may extend in the first horizontal direction D1 across the semiconductor patterns SP within one layer.

In some exemplary embodiments, the word line WL may be disposed on each semiconductor pattern SP that extends in the second horizontal direction D2 and is disposed to be spaced apart from each other in the first horizontal direction D1 at the same level. The word line WL may intersect each semiconductor pattern SP that extends in the second horizontal direction D2 and is disposed to be spaced apart from another semiconductor pattern SP in the first horizontal direction D1 at the same level. A width of the word line WL in the first horizontal direction D1 may be greater than a width of the semiconductor pattern SP in the first horizontal direction D1.

In some exemplary embodiments, the cell transistor TR of FIG. 2 may be a gate-all-around transistor. The word line WL may surround the channel region CH. The word line WL may surround the outer circumferential surface of the channel region CH. The word line WL may surround the channel region CH of each semiconductor pattern SP that extends in the second horizontal direction D2 and is disposed to be spaced apart from another semiconductor pattern SP in the first horizontal direction D1 at the same level.

Unlike illustrated, in some exemplary embodiments, the cell transistor TR of FIG. 2 may have a double gate transistor structure. The word lines WL may be spaced apart from each other by being disposed on opposite side walls (e.g., opposite side walls in the vertical direction D3) of the channel region CH. In some other exemplary embodiments, the word line WL may be disposed on one side wall of the channel region CH.

The word lines WL and the interlayer insulating patterns ILD may extend from the bit line connection region BLB to the word line connection region WLB. The word lines WL and the interlayer insulating patterns ILD may have a step structure in the word line connection region WLB. For example, in the word line connection region WLB, the word lines WL may have a length that increases in the first horizontal direction D1 toward an upward direction.

The word line WL may include a conductive material. For example, the word line WL may include at least one of a doped semiconductor material, a conductive metal nitride, a metal, and a metal-semiconductor compound, but is not limited thereto.

The gate insulating film GI may be disposed between the word line WL and the semiconductor pattern SP, and between the word line WL and the interlayer insulating pattern ILD. The gate insulating film GI may extend along upper and lower surfaces of the word line WL, and along one side wall extending in the vertical direction D3 and adjacent to the spacer insulating pattern SS.

The gate insulating film GI may include, for example, at least one of a high-k insulating film, a silicon oxide film, a silicon nitride film, and a silicon oxynitride film.

The capping insulating pattern CP may be disposed between the second impurity region SD2 of the semiconductor pattern SP and the interlayer insulating pattern ILD. The capping insulating pattern CP may be disposed on the upper and lower surfaces of the semiconductor pattern SP. The capping insulating pattern CP may spatially separate the first and second local bit lines LBL1 and LBL2 and the word line WL. The gate insulating film GI may be interposed between the capping insulating pattern CP and the interlayer insulating pattern ILD, and between the capping insulating pattern CP and the semiconductor pattern SP.

The spacer insulating pattern SS may be disposed between the first impurity region SD1 of the semiconductor pattern SP and the interlayer insulating pattern ILD. The spacer insulating pattern SS may be disposed on the upper and lower surfaces of the semiconductor pattern SP. The spacer insulating pattern SS may be spaced apart from the word line WL with the gate insulating film GI interposed therebetween. The gate insulating film GI may be interposed between the spacer insulating pattern SS and the interlayer insulating pattern ILD, and between the spacer insulating pattern SS and the semiconductor pattern SP.

The capping insulating pattern CP and the spacer insulating pattern SS may each include, for example, at least one of a silicon oxide film, a silicon nitride film, a silicon oxynitride film, a carbon-containing silicon oxide film, a carbon-containing silicon nitride film, and a carbon-containing silicon oxynitride film.

The first and second separation insulating patterns STI1 and STI2 may be disposed on the first lower insulating layer 10. The first separation insulating pattern STI1 may be disposed between the first and second local bit lines LBL1 and LBL2 adjacent to each other in the first horizontal direction D1. The second separation insulating pattern STI2 may be disposed between the storage electrodes SE adjacent to each other in the first horizontal direction D1.

The buried insulating pattern 105 may be disposed on the first lower insulating layer 10. The buried insulating pattern 105 may cover side walls of the first and second local bit lines LBL1 and LBL2 and a side wall of the first separation insulating pattern STI1.

The first and second separation insulating patterns STI1 and STI2 and the buried insulating pattern 105 may each be formed of at least one of insulating materials, silicon oxide, and silicon oxynitride, which are formed using spin on glass (SOG) technology.

The data storage element CAP may be disposed on a plurality of semiconductor patterns SP and interlayer insulating patterns ILD. The data storage element CAP and the first and second local bit lines LBL1 and LBL2 may be respectively disposed at two ends of the semiconductor pattern SP opposite to each other in the second horizontal direction D2. The data storage element CAP may include a capacitor dielectric film CIL, a plurality of storage electrodes SE, and a plate electrode PE. Each data storage element CAP may include a storage electrode SE, a capacitor dielectric film CIL, and a plate electrode PE disposed between the interlayer insulating patterns ILD. Each data storage element CAP may be defined by each storage electrode SE.

The capacitor dielectric film CIL may be disposed on the storage electrode SE and the interlayer insulating pattern ILD. The capacitor dielectric film CIL may extend along a profiles of the plurality of storage electrodes SE and side surfaces of the plurality of interlayer insulating patterns ILD. The plate electrode PE may be disposed on the capacitor dielectric film CIL. The capacitor dielectric film CIL and the plate electrode PE may be sequentially disposed on the storage electrode SE.

The capacitor dielectric film CIL and the plate electrode PE that are included in each data storage element CAP may be connected to each other.

The storage electrode SE and the plate electrode PE may each include, for example, a doped semiconductor material, a conductive metal nitride (e.g., a titanium nitride, a tantalum nitride, a niobium nitride, a tungsten nitride, or the like), a metal (e.g., ruthenium, iridium, titanium, tantalum, or the like), a conductive metal oxide (e.g., an iridium oxide, a niobium oxide, or the like), and the like, but are not limited thereto. As an example, the storage electrode SE may include a conductive metal nitride, a metal, and a conductive metal oxide. The conductive metal nitride, the metal, and the conductive metal oxide may be included in the metallic conductive film.

The capacitor dielectric film CIL may include, for example, a high-k material (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof). In the semiconductor memory device according to some exemplary embodiments, the capacitor dielectric film CIL may include a stacked film structure in which zirconium oxide, aluminum oxide, and zirconium oxide are sequentially stacked. In the semiconductor memory device according to some exemplary embodiments, the capacitor dielectric film CIL may include hafnium (Hf).

The first cell insulating layer 106 may be disposed on a lower surface of the lowermost word line WL based on the vertical direction D3. The first cell insulating layer 106 may be disposed between the plate electrode PE and the first and second local bit lines LBL1 and LBL2. The first cell insulating layer 106 may be disposed on the bit line connection region BLB.

The second cell insulating layer 107 may cover the step structure of word lines WL and the interlayer insulating patterns ILD. A lower surface of the second cell insulating layer 107 may be positioned at substantially the same level as a lower surface of the first cell insulating layer 106. The second cell insulating layer 107 may be disposed on the word line connection region WLB.

The first and second lower insulating layers 10 and 20 may be disposed on the lower surface of the memory cell layer MSL. The first and second lower insulating layers 10 and 20 may be disposed below the word lines WL. The first lower insulating layer 10 may be disposed on the lower surface of the plate electrode PE, the lower surface of the first cell insulating layer 106, and the lower surface of the second cell insulating layer 107. The second lower insulating layer 20 may be disposed on the lower surface of the first lower insulating layer 10.

The first global bit line GBL1 and the first bit line contact 12 may be disposed within the first lower insulating layer 10. The first global bit line GBL1 may be disposed below the first local bit line LBL1. The first bit line contact 12 may be disposed between the first local bit line LBL1 and the first global bit line GBL1. The first bit line contact 12 may be in contact with the first global bit line GBL1 and the first local bit line LBL1. The first global bit line GBL1 and the first bit line contact 12 may be disposed in the bit line connection region BLB.

Connection lines WCL may be disposed within the first lower insulating layer 10. Word line contacts 108 may be disposed within the second cell insulating layer 107 and the first lower insulating layer 10. The word line contacts 108 may be disposed on the lower surface of word lines WL having the step structure. Each word line contact 108 may be disposed on each word line WL. Each word line contact 108 may be in contact with each word line WL and each connection line WCL. The connection line WCL may be electrically connected to the word line WL. The connection lines WCL and the word line contacts 108 may be disposed in the word line connection region WLB.

The lower conductive patterns 21 and 22 may be disposed within the second lower insulating layer 20. The lower conductive patterns 21 and 22 may include lower wirings 21 and lower vias 22. The lower conductive patterns 21 and 22 may be electrically connected to the first global bit line GBL1.

The first and second upper insulating layers 30 and 40 may be disposed on the upper surface of the memory cell layer MSL. The memory cell layer MSL may be disposed between the first and second lower insulating layers 10 and 20 and the first and second upper insulating layers 30 and 40. The first and second upper insulating layers 30 and 40 may be disposed above the word lines WL. The first upper insulating layer 30 may be disposed on an upper surface of the uppermost interlayer insulating pattern ILD. The second upper insulating layer 40 may be disposed on the upper surface of the first upper insulating layer 30.

The second global bit line GBL2 and the second bit line contact 32 may be disposed within the first upper insulating layer 30. The second global bit line GBL2 may be disposed above the second local bit line LBL2. The second bit line contact 32 may be disposed above the second local bit line LBL2. The second bit line contact 32 may be disposed between the second local bit line LBL2 and the second global bit line GBL2. The second bit line contact 32 may be in contact with the second local bit line LBL2 and the second global bit line GBL2. The second global bit line GBL2 and the second bit line contact 32 may be disposed in the bit line connection region BLB.

The upper conductive patterns 41 and 42 may be disposed within the second upper insulating layer 40. The upper conductive patterns 41 and 42 may include upper wirings 41 and upper vias 42. The upper conductive patterns 41 and 42 may be electrically connected to the second global bit line GBL2.

The number of lower wirings 21 and lower vias 22 and the connection relationship therebetween, and the number of upper wirings 41 and upper vias 42 and the connection relationship therebetween may be variously changed. The number of upper insulating layers 30 and 40 disposed above the memory cell layer MSL and the number of lower insulating layers 10 and 20 disposed below the memory cell layer MSL may be variously changed.

A first peripheral connection line 11 may be disposed within the first lower insulating layer 10. The first peripheral connection line 11 may be electrically connected to the lower conductive patterns 21 and 22. A second peripheral connection line 31 may be disposed within the first upper insulating layer 30. The second peripheral connection line 31 may be electrically connected to the upper conductive patterns 41 and 42. A contact 109 may be disposed within the second cell insulating layer 107, the first lower insulating layer 10, and the first upper insulating layer 30. The contact 109 may connect the first peripheral connection line 11 and the second peripheral connection line 31. The first peripheral connection line 11, the second peripheral connection line 31, and the contact 109 may be disposed within the word line connection region WLB. The first peripheral connection line 11, the second peripheral connection line 31, and the contact 109 may be disposed, for example, at an edge portion of the word line connection region WLB.

The first peripheral circuit structure PS1 may include a first semiconductor layer 100, first core transistors CTR1, a first insulating layer 110, and first conductive patterns 111 and 112.

In some exemplary embodiments, the first semiconductor layer 100 may include a semiconductor substrate such as a silicon substrate, a germanium substrate, or a silicon-germanium substrate. Alternatively, the first semiconductor layer 100 may also include a silicon-on-insulator (SOI) substrate or a germanium-on-insulator (GOI) substrate.

In some exemplary embodiments, the first semiconductor layer 100 may include at least one of the single crystal semiconductor, the polycrystalline semiconductor, the oxide semiconductor, and the two-dimensional material described above.

The first core transistors CTR1 and third core transistors CTR3 may be disposed on the first semiconductor layer 100. Hereinafter, a front surface of the first semiconductor layer 100 refers to one surface on which the first core transistors CTR1 and the third core transistors CTR3 are disposed. This surface may also be described as the active surface. The first core transistors CTR1 may be disposed in the first region R1. The first core transistors CTR1 may form the first sense amplifier SA1. The third core transistors CTR3 may be disposed in the third region R3. The third core transistors CTR3 may form the sub word line driver SWD.

In some exemplary embodiments, the front surface of the first semiconductor layer 100 may face the cell structure CS.

The first insulating layer 110 may be disposed on the front surface of the first semiconductor layer 100. The first insulating layer 110 may cover the first semiconductor layer 100, the first core transistors CTR1, and the third core transistors CTR3.

The first conductive patterns 111 and 112 may be disposed on the front surface of the first semiconductor layer 100. The first conductive patterns 111 and 112 may include first wirings 111 and first vias 112. The first conductive patterns 111 and 112 may be disposed within the first insulating layer 110. The first conductive patterns 111 and 112 may be electrically connected to the first core transistors CTR1 and the third core transistor CTR3.

The second peripheral circuit structure PS2 may include a second semiconductor layer 200, second core transistors CTR2, a second insulating layer 210, and second conductive patterns 211 and 212.

In some exemplary embodiments, the second semiconductor layer 200 may include or be a semiconductor substrate such as a silicon substrate, a germanium substrate, or a silicon-germanium substrate. Alternatively, the second semiconductor layer 200 may also include or be a silicon-on-insulator (SOI) substrate or a germanium-on-insulator (GOI) substrate.

In some exemplary embodiments, the second semiconductor layer 200 may include at least one of the single crystal semiconductor, the polycrystalline semiconductor, the oxide semiconductor, and the two-dimensional material described above.

The second core transistors CTR2 and peripheral transistors PTR may be disposed on the second semiconductor layer 200. A front surface of the second semiconductor layer 200 refers to one surface on which the second core transistors CTR2 and the peripheral transistors PTR are disposed. The second core transistors CTR2 may be disposed in the second region R2. The second core transistors CTR2 may form the second sense amplifier SA2. The peripheral transistors PTR may be disposed in the fourth region R4. The peripheral transistors PTR may form the control signal generation circuit described with reference to FIG. 3. The peripheral transistors PTR may be control transistors. The core transistors described herein may be access transistors that control read/write access to memory cells, and the core transistors and control transistors described herein may be peripheral transistors formed in the peripheral circuit regions of the semiconductor device, used to operate the memory cell array. For example, the core transistors may be peripheral transistors that perform certain functions, and the control transistors (described as peripheral transistors PTR) may be other peripheral transistors that perform other functions. These general peripheral transistors may also be described as operational transistors, and are different from the cell transistors, which may be selection transistors that select whether to turn on or off a connection to a data storage element and are controlled by the operational transistors.

In some exemplary embodiments, the front surface of the second semiconductor layer 200 may face the cell structure CS.

The second conductive patterns 211 and 212 may be disposed on the front surface of the second semiconductor layer 200. The second conductive patterns 211 and 212 may include second wirings 211 and second vias 212. The second conductive patterns 211 and 212 may be disposed within the second insulating layer 210. The second conductive patterns 211 and 212 may be electrically connected to the second core transistors CTR2 and the peripheral transistor PTR. The second core transistors CTR2 may be electrically connected to the peripheral transistors PTR through the second conductive patterns 211 and 212.

The first to third core transistors CTR1, CTR2, and CTR3 and the peripheral transistors PTR may each include a gate insulating pattern 131, a gate electrode 133, a gate capping pattern 135, a gate spacer 137, and source/drain regions 139. The gate insulating pattern 131 may be disposed between the gate electrode 133 and the first semiconductor layer 100 and between the gate electrode 133 and the second semiconductor layer 200. The gate capping pattern 135 may be disposed on the gate electrode 133. The gate spacer 137 may cover side walls of the gate insulating pattern 131, the gate electrode 133, and the gate capping pattern 135. The source/drain regions 139 may be provided within the first semiconductor layer 100 and the second semiconductor layer 200 adjacent to both sides of the gate electrode 133.

An input/output pad 220 may be disposed on a back surface of the second semiconductor layer 200. The input/output pad 220 may be electrically connected to the second conductive patterns 211 and 212 through a connection via 215 in the second semiconductor layer 200 and the second insulating layer 210. For example, the input/output pad 220 may be disposed in the fourth region R4, but is not limited thereto.

The first and second global bit lines GBL1 and GBL2, the connection line WCL, the first and second peripheral connection lines 11 and 31, the first and second bit line contacts 12 and 32, the word line contact 108, the lower conductive patterns 21 and 22, the upper conductive patterns 41 and 42, the first conductive patterns 111 and 112, the second conductive patterns 211 and 212, the contact 109, the connection via 215, and the input/output pad 220 may each include or be formed of a conductive material, such as a metal, for example. The first and second cell insulating layers 106 and 107, the first and second lower insulating layers 10 and 20, the first and second upper insulating layers 30 and 40, and the first and second insulating layers 110 and 210 may each include or be formed of an insulating material.

The semiconductor memory device may have a chip-to-chip (C2C) structure bonded by a wafer bonding method. For example, the semiconductor memory device may be manufactured by manufacturing the memory cell layer MSL, the first peripheral circuit structure PS1, and the second peripheral circuit structure PS2, and then bonding them.

In some exemplary embodiments, a lower bonding pad 25 of the cell structure CS and a first bonding pad 125 of the first peripheral circuit structure PS1 may be connected to each other, and an upper bonding pad 45 of the cell structure CS and a second bonding pad 245 of the second peripheral circuit structure PS2 may be connected to each other.

The cell structure CS may include the lower bonding pad 25 on the lower conductive patterns 21 and 22 and the upper bonding pad 45 on the upper conductive patterns 61 and 62, the first peripheral circuit structure PS1 may include the first bonding pad 125 on the first conductive patterns 111 and 112, and the second peripheral circuit structure PS2 may include the second bonding pad 245 on the second conductive patterns 211 and 212. The lower bonding pad 25 may be disposed on the lowest metal layer within the second lower insulating layer 20. The upper bonding pad 45 may be disposed on the uppermost metal layer within the upper insulating layer 40. The first bonding pad 125 may be disposed on the uppermost metal layer on the front surface of the first semiconductor layer 100 within the first insulating layer 110. The second bonding pad 245 may be disposed on the uppermost metal layer on the front surface of the second semiconductor layer 200 within the second insulating layer 210.

The lower bonding pad 25 and the first bonding pad 125 may be in contact with each other. The first global bit line GBL1 may be electrically connected to the first core transistors CTR1 through the lower conductive patterns 21 and 22, the lower bonding pad 25, the first bonding pad 125, and the first conductive patterns 111 and 112. The first global bit line GBL1 may be electrically connected to the first core transistors CTR1 (i.e., the first sense amplifier SA1), and the first local bit lines LBL1 may be electrically connected to the first core transistors CTR1 through the first global bit line GBL1. The connection line WCL may be electrically connected to the third core transistors CTR3 through the lower conductive patterns 21 and 22, the lower bonding pad 25, the first bonding pad 125, and the first conductive patterns 111 and 112. The connection line WCL may be electrically connected to the third core transistors CTR3 (i.e., the sub word line driver SWD), and the word line WL may be electrically connected to the third core transistors CTR3 through the connection line WCL.

The first and third core transistors CTR1 and CTR3 may be electrically connected to the peripheral transistors PTR through the first conductive patterns 111 and 112, the first bonding pad 125, the lower bonding pad 25, the lower conductive patterns 21 and 22, the first peripheral connection line 11, the contact 109, the second peripheral connection line 31, the upper conductive patterns 41 and 42, the upper bonding pad 45, the second bonding pad 245, and the second conductive patterns 211 and 212.

The upper bonding pad 45 and the second bonding pad 245 may be in contact with each other. The second global bit line GBL2 may be electrically connected to the second core transistors CTR2 through the upper conductive patterns 41 and 42, the upper bonding pad 45, the second bonding pad 245, and the second conductive patterns 211 and 212. The second global bit line GBL2 may be electrically connected to the second core transistors CTR2 (i.e., the second sense amplifier SA2), and the second local bit lines LBL2 may be electrically connected to the second core transistors CTR2 through the second global bit line GBL2.

The lower bonding pad 25, the upper bonding pad 45, the first bonding pad 125, and the second bonding pad 245 may include the same material, and may be formed of the same conductive material as each other, such as a metal. The lower bonding pad 25, the upper bonding pad 45, the first bonding pad 125, and the second bonding pad 245 may include or may be, for example, copper (Cu), aluminum (Al), nickel (Ni), cobalt (Co), tungsten (W), titanium (Ti), tin (Sn), or an alloy thereof. For example, when the lower bonding pad 25, the upper bonding pad 45, the first bonding pad 125, and the second bonding pad 245 are formed of copper (Cu), the cell structure CS and the first peripheral circuit structure PS1, and the cell structure CS and the second peripheral circuit structure PS2 may be bonded to each other by a Cu to Cu bonding method.

In the semiconductor memory device according to some exemplary embodiments, the first global bit lines GBL1 connecting first local bit lines LBL1 disposed in odd-numbered rows are disposed on the lower surface of the memory cell layer MSL, and the second global bit lines GBL2 connecting second local bit lines LBL2 disposed in even-numbered rows are disposed on the upper surface of the memory cell layer MSL. Therefore, a distance between the connection lines in the first horizontal direction D1 at a particular level in the vertical direction D3 increases, compared to the case where the connection lines connecting the bit lines arranged in the second horizontal direction D2 are disposed on only a top or only a bottom of the memory cell layer MSL. Therefore, a capacitance between the global bit lines GBL1 and GBL2 adjacent to each other may be reduced, and a sensing margin may be improved or enhanced. In addition, since the transistors CTR1, CTR2, CTR3, and PTR are disposed on both sides of the memory cell layer MSL (e.g., on a top and bottom of the memory cell layer MSL), the design freedom, such as the number and size of the first and second core transistors CTR1 and CTR2 that form the first and second sense amplifiers SA1 and SA2, and the design freedom, such as the number and size of the third core transistors CTR3 that form the sub word line driver SWD may be improved or enhanced, and an area of the semiconductor memory device may be reduce. In addition, a space where a Processing in Memory (PIM), such as an NPU, may be disposed in the semiconductor memory device may be secured.

As can be seen in FIGS. 1-9, a vertical memory device, such as a DRAM in one example, may include vertically stacked data storage elements (e.g., CAP), such as capacitors, connected to vertical bit lines (e.g., LBL1 and LBL2), through horizontally-extending semiconductor patterns (e.g., SP) surrounded by word lines (e.g., WL). For example, each vertical bit line (e.g., LBL1 or LBL2) may extend in a vertical direction (e.g., D3) and be connected to a plurality of horizontally-extending semiconductor patterns (e.g., SP) extending in a particular horizontal direction (e.g., second horizontal direction D2) that each connect at a first end to the vertical bit line and at a second opposite end to a respective data storage element (e.g., CAP). Furthermore, each word line (e.g., WL) may extend in a particular horizontal direction (e.g., first horizontal direction D1) crossing the horizontal direction in which the semiconductor patterns extend (e.g., perpendicular to the second horizontal direction) to cross a plurality of the semiconductor patterns at the same vertical level. According to some embodiments, global bit lines (e.g., GBL1 and GBL2), which extend horizontally, are used to connect certain of the vertical bit lines together. For example, each global bit line may extend in the second horizontal direction D2 to connect a plurality vertical bit lines to each other in common, thereby connecting one end of a plurality of semiconductor patterns to each other in common. A first set of global bit lines (e.g., GBL1) may be disposed at a first vertical level, so that each global bit line of the first set connects to a bottom of a corresponding group of vertical bit lines (e.g., LBL1), and a second set of global bit lines (e.g., GBL2) may be disposed at a second vertical level, so that each global bit line of the second set connects to a top of a corresponding group of vertical bit lines (e.g., LBL2). The global bit lines of the first set may be alternatingly arranged with the global bit lines of the second set along the first horizontal direction D1, so that along the first horizontal direction D1, two global bit lines at a particular vertical level (e.g., above the memory cell layer MSL) are separated by a global bit line at a different vertical level (e.g., below the memory cell layer MSL).

For example a semiconductor memory device such as shown in FIGS. 1-9 can be a three-dimensional memory cell array including memory cells MC including cell transistors TR arranged in a three-dimensional array and corresponding data storage elements CAP arranged in a three-dimensional array. According to some embodiments, the semiconductor memory device includes a plurality of word lines WL extending lengthwise in a first horizontal direction D1, and spaced apart from each other in a vertical direction D3 and a second horizontal direction D2 crossing the first horizontal direction. Each cell transistor may include a semiconductor pattern SP extending lengthwise in the second horizontal direction D2 and having a first end connected to a respective data storage element CAP, each semiconductor pattern crossing a word line WL of the plurality of word lines. The semiconductor memory device may include first local bit lines LBL1 crossing the word lines WL and second local bit lines LBL2 intersecting the word lines WL, wherein each bit line of the first local bit lines LBL1 and second local bit lines LBL2 extend lengthwise in the vertical direction. The semiconductor memory device may further include first global bit lines GBL1 extending lengthwise in the second horizontal direction D2 and electrically connected to the first local bit lines LBL1, below the word lines WL, and second global bit lines GBL2 extending lengthwise in the second horizontal direction D2 and electrically connected to the second local bit lines LBL2, above the word lines WL.

According to some embodiments, each first global bit line GBL1 electrically connected to first local bit lines LBL1 electrically connects a group of first local bit lines LBL1 arranged in the second horizontal direction D2, each second global bit line GBL2 electrically connected to second local bit lines LBL2 electrically connects a group of second local bit lines LBL2 arranged in the second horizontal direction D2, and when viewed in a plan view (i.e., from the vertical direction D3), the first global bit lines GBL1 and second global bit lines GBL2 are alternatingly arranged along the first horizontal direction D1. In addition, a first peripheral circuit, such as included in first peripheral circuit region PS1, may be formed below the first global bit lines GBL1, may be electrically connected to the first global bit lines GBL1, and may include transistors (e.g., peripheral transistors such as CTR1 and CTR3) for controlling a first group of the memory cells, and a second peripheral circuit, such as included in second peripheral circuit region PS2, may be formed above the second global bit lines GBL2, may be electrically connected to the second global bit lines GBL2, and may include transistors (e.g., peripheral transistors such as CTR3 and PTR) for controlling a second group of the memory cells.

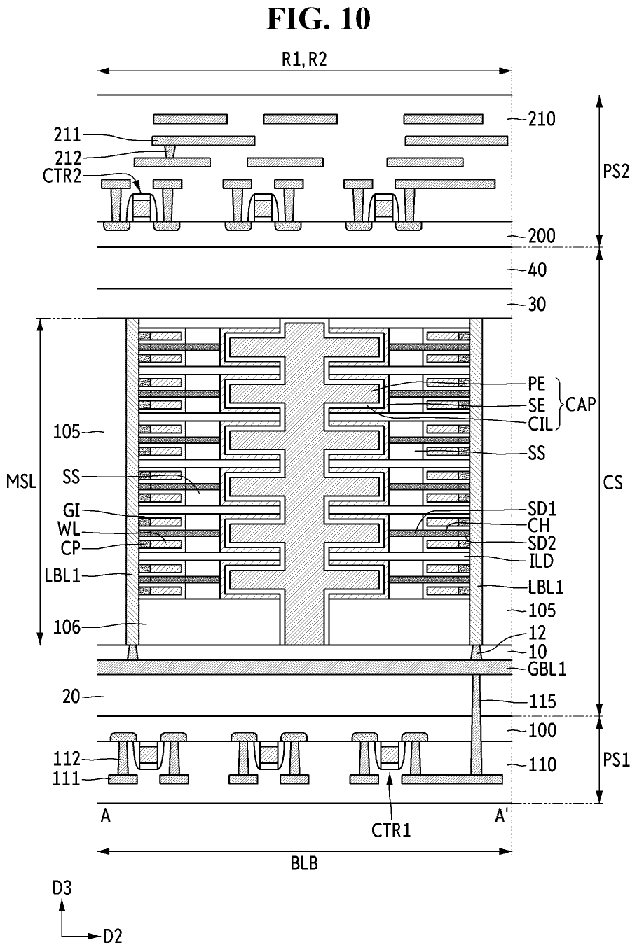

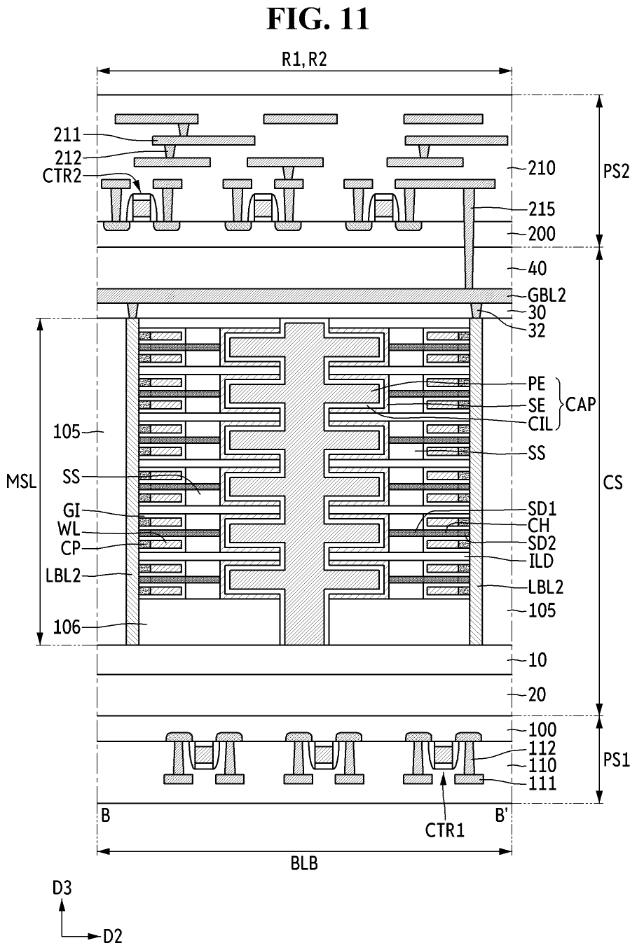

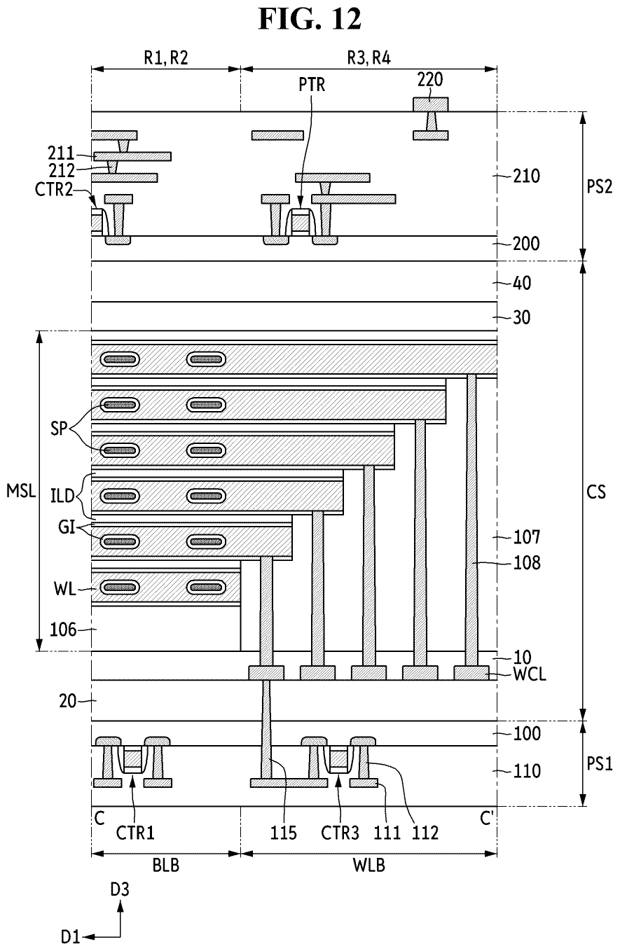

FIGS. 10 to 12 are views for describing a semiconductor memory device according to some exemplary embodiments. FIG. 10 is a cross-sectional view taken along line A-A′ of FIGS. 4 and 5, FIG. 11 is a cross-sectional view taken along line B-B′ of FIGS. 4 and 5, and FIG. 12 is a cross-sectional view taken along line C-C′ of FIGS. 4 and 5. For convenience of explanation, portions overlapping those described above with reference to FIGS. 1 to 9 will be briefly described, and differences will be mainly described.

Referring to FIGS. 10 to 12, in the semiconductor memory device according to some exemplary embodiments, the cell structure CS and the first peripheral circuit structure PS1 may be electrically connected through a first connection via 115, and the cell structure CS and the second peripheral circuit structure PS2 may be electrically connected through a second connection via 215. The first and second connection vias 115 and 215 may each include a conductive material.

The front surface of the first semiconductor layer 100 may face away from the cell structure CS. The first semiconductor layer 100 may be disposed between the second lower insulating layer 20 and the first insulating layer 110. The first connection via 115 may connect the first global bit line GBL1 and the first conductive patterns 111 and 112. The first global bit line GBL1 may be electrically connected to the first core transistors CTR1 through the first connection via 115 and the first conductive patterns 111 and 112. The first connection via 115 may be disposed within the first insulating layer 110, the first semiconductor layer 100, and the second lower insulating layer 20. An insulating pattern may be disposed on a side surface of the first connection via 115. The connection line WCL may be electrically connected to the third core transistors CTR3 through the first connection via 115 and the first conductive patterns 111 and 112.

Unlike illustrated, conductive patterns may be disposed within the second lower insulating layer 20, and the first connection via 115 may be connected to the conductive patterns within the second lower insulating layer 20.

The back surface of the second semiconductor layer 200 may face the cell structure CS. The second semiconductor layer 200 may be disposed between the second upper insulating layer 40 and the second insulating layer 210. An insulating pattern may be disposed on a side surface of the second connection via 215. The second connection via 215 may connect the second global bit line GBL2 and the second conductive patterns 211 and 212. The second global bit line GBL2 may be electrically connected to the second core transistors CTR2 through the second connection via 215 and the second conductive patterns 211 and 212. The second connection via 215 may be disposed within the second insulating layer 210, the second semiconductor layer 200, and the second upper insulating layer 40.

Unlike illustrated, conductive patterns may be disposed within the second upper insulating layer 40, and the second connection via 215 may be connected to the conductive patterns within the second upper insulating layer 40.

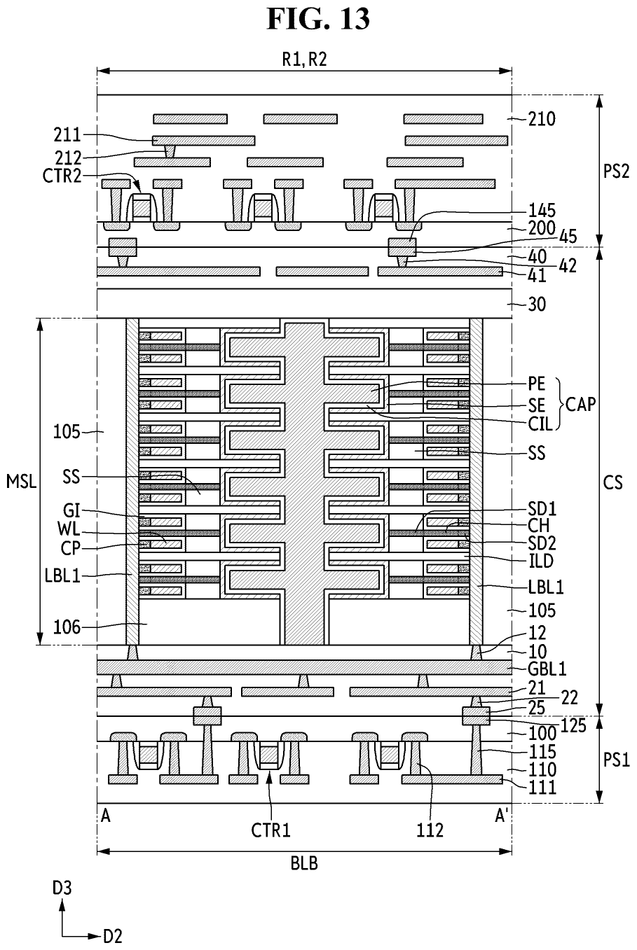

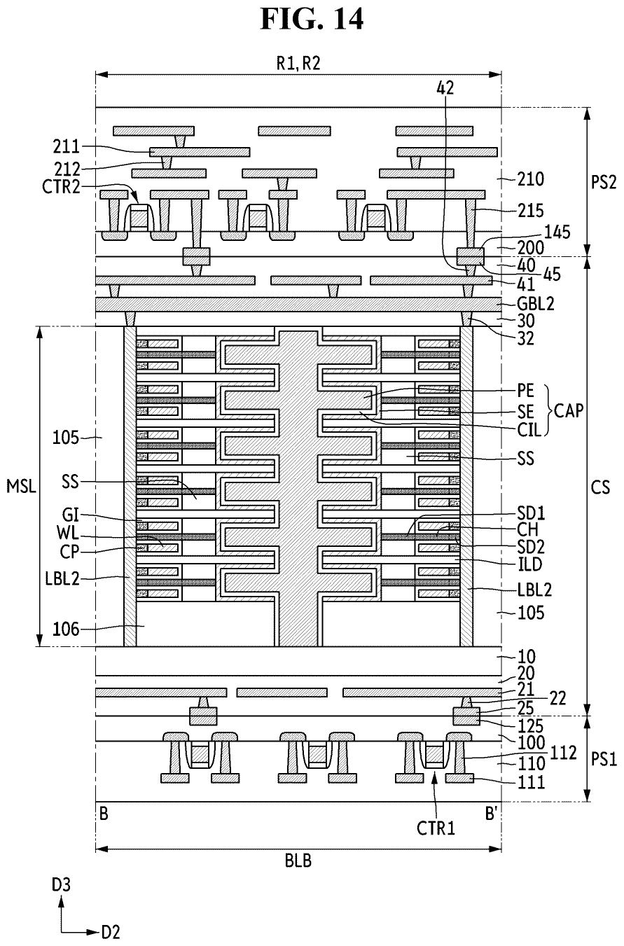

FIGS. 13 to 15 are views for describing a semiconductor memory device according to some exemplary embodiments. FIG. 13 is a cross-sectional view taken along line A-A′ of FIGS. 4 and 5, FIG. 14 is a cross-sectional view taken along line B-B′ of FIGS. 4 and 5, and FIG. 15 is a cross-sectional view taken along line C-C′ of FIGS. 4 and 5. For convenience of explanation, portions overlapping those described above with reference to FIGS. 1 to 9 will be briefly described, and differences will be mainly described.

Referring to FIGS. 13 to 15, in the semiconductor memory device according to some exemplary embodiments, the front surface of the first semiconductor layer 100 may face away from the cell structure CS, and the back surface of the second semiconductor layer 200 may face the cell structure CS.

The first connection via 115 may be disposed within the first insulating layer 110 and the first semiconductor layer 100. An insulating pattern may be disposed on a side surface of the first connection via 115. The first connection via 115 may connect the first bonding pad 125 and the first conductive patterns 111 and 112. The first global bit line GBL1 may be electrically connected to the first core transistors CTR1 through the lower conductive patterns 21 and 22, the lower bonding pad 25, the first bonding pad 125, the first connection via 115, and the first conductive patterns 111 and 112. The connection line WCL may connect the first bonding pad 125 and the first conductive patterns 111 and 112. The first global bit line GBL1 may be electrically connected to the third core transistors CTR3 through the lower conductive patterns 21 and 22, the lower bonding pad 25, the first bonding pad 125, the first connection via 115, and the first conductive patterns 111 and 112. The first connection via 115 may include a conductive material.

The second connection via 215 may be disposed within the second insulating layer 210 and the second semiconductor layer 200. An insulating pattern may be disposed on a side surface of the second connection via 215. The second connection via 215 may connect the second bonding pad 145 and the second conductive patterns 211 and 212. The second global bit line GBL2 may be electrically connected to the second core transistors CTR2 through the upper conductive patterns 41 and 42, the upper bonding pad 45, the second bonding pad 145, the second connection via 215, and the second conductive patterns 211 and 212. The second connection via 215 may include a conductive material.

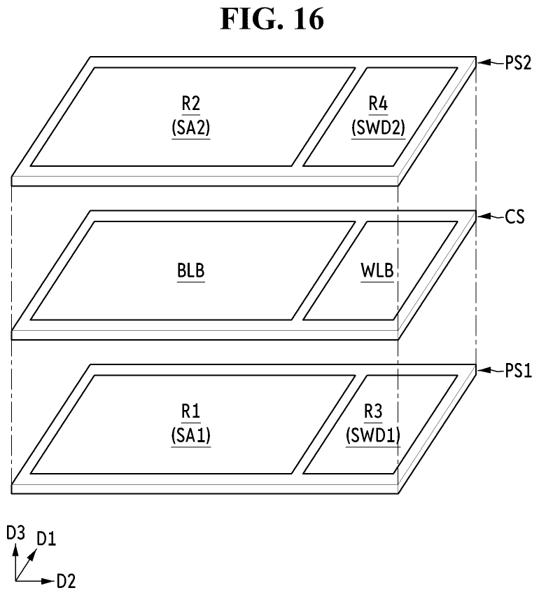

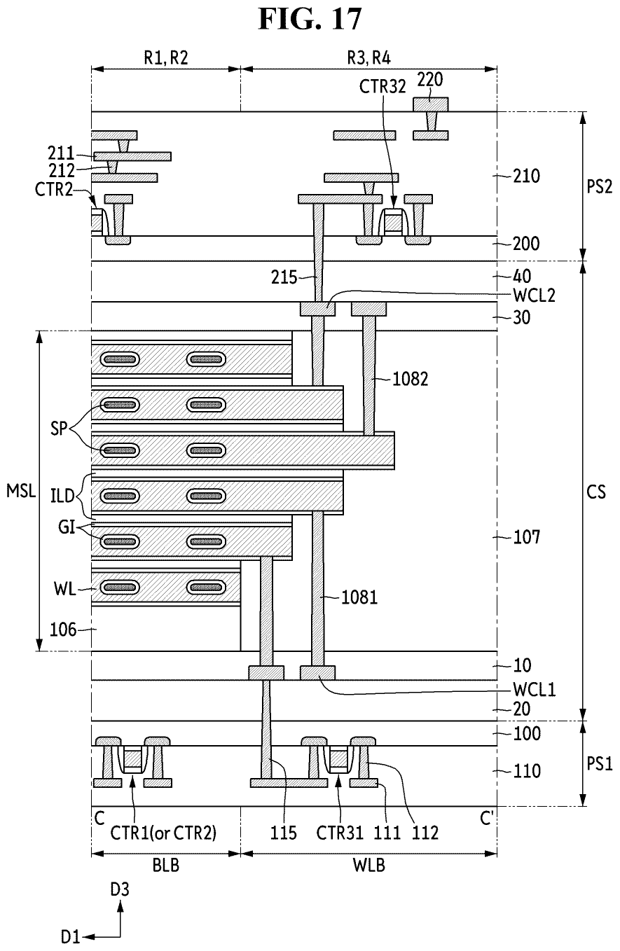

FIGS. 16 and 17 are views for describing a semiconductor memory device according to some exemplary embodiments. FIG. 17 is a cross-sectional view taken along line C-C′ of FIGS. 4 and 5. For convenience of explanation, portions overlapping those described above with reference to FIGS. 1 to 9 will be briefly described, and differences will be mainly described.

Referring to FIGS. 16 and 17, in the semiconductor memory device according to some exemplary embodiments, a portion of the sub word line driver SWD of FIG. 1, i.e., the first sub word line driver SWD1, may be disposed in the third region R3 of the first peripheral circuit structure PS1, and the remainder, i.e., the second sub word line driver SWD2, may be disposed in the fourth region R4 of the second peripheral circuit structure PS2.

In the word line connection region WLB, the length of the word lines WL in the first horizontal direction D1 may increase and then decrease toward the upward direction. In the word line connection region WLB, the first word lines disposed at the lower portion among the word lines WL may have a step structure in which the length in the first horizontal direction D1 increases toward the upward direction, and the second word lines disposed at the upper portion among the word lines WL may have a step structure in which the length in the first horizontal direction D1 decreases toward the upward direction.

First connection lines WCL1 may be disposed within the first lower insulating layer 10. First word line contacts 1081 may be disposed within the second cell insulating layer 107 and the first lower insulating layer 10. The first word line contacts 1081 may be disposed on lower surfaces of the first word lines. Each first word line contact 1081 may be in contact with each first word line and each first connection line WCL1. The first connection line WCL1 may be electrically connected to the first word line. The first connection lines WCL1 and the first word line contacts 1081 may be disposed in the word line connection region WLB. The first connection lines WCL1 and the first word line contacts 1081 may each include a conductive material.

Third_first core transistors CTR31 may be disposed on the first semiconductor layer 100. The third_first core transistors CTR31 may form the first sub word line driver SWD1. The third_first core transistors CTR31 may be disposed in the third region R3. The first connection line WCL1 may be electrically connected to the third_first core transistors CTR31 through the first connection via 115 and the first conductive patterns 111 and 112. The first connection line WCL1 may be electrically connected to the third_first core transistors CTR31 (i.e., the first sub word line driver SWD1), and the first word line may be electrically connected to the third_first core transistors CTR31 through the first connection line WCL1.

Unlike illustrated, conductive patterns may be disposed within the second lower insulating layer 20, and the first connection via 115 may be connected to the conductive patterns within the second lower insulating layer 20.

Second connection lines WCL2 may be disposed within the first upper insulating layer 30. Second word line contacts 1082 may be disposed within the second cell insulating layer 107 and the first upper insulating layer 30. The second word line contacts 1082 may be disposed on upper surfaces of the second word lines. Each second word line contact 1082 may be in contact with each second word line and each second connection line WCL2. The second connection line WCL2 may be electrically connected to the second word line. The second connection lines WCL2 and the second word line contacts 1082 may be disposed in the word line connection region WLB. The second connection lines WCL2 and the second word line contacts 1082 may each include a conductive material.

Third_second core transistors CTR32 may be disposed on the second semiconductor layer 200. The third_second core transistors CTR32 may form the second sub word line driver SWD2. The third_second core transistors CTR32 may be disposed in the fourth region R4. The second connection line WCL2 may be electrically connected to the third_second core transistors CTR32 through the second connection via 215 and the second conductive patterns 211 and 212. The second connection line WCL2 may be electrically connected to the third_second core transistors CTR32 (i.e., the second sub word line driver SWD2), and the second word line may be electrically connected to the third_second core transistors CTR32 through the second connection line WCL2. The first and second connection lines WCL1 and WCL2 may each be referred to as global word lines.

Unlike illustrated, conductive patterns may be disposed within the second upper insulating layer 40, and the second connection via 215 may be connected to the conductive patterns within the second upper insulating layer 40.

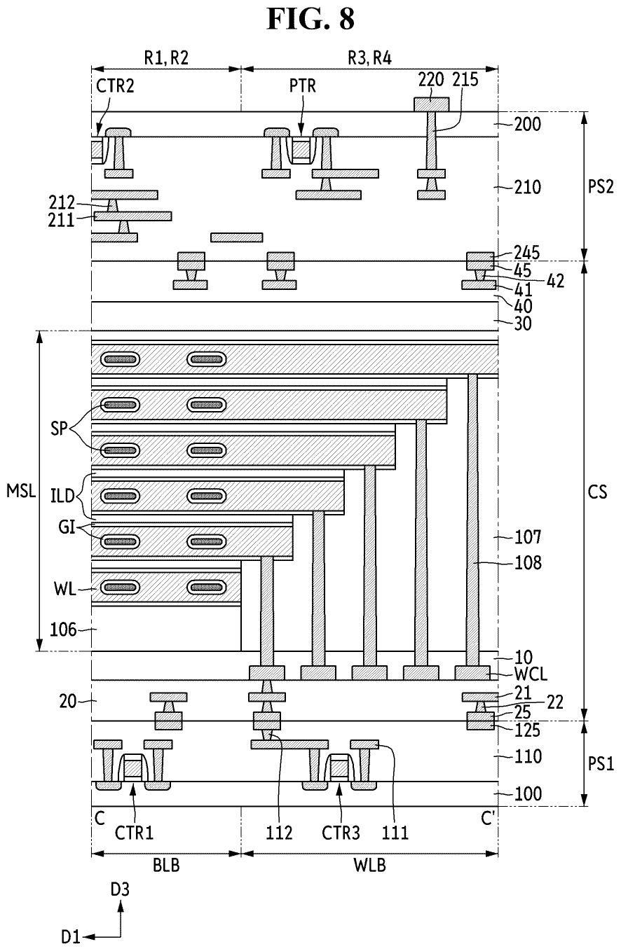

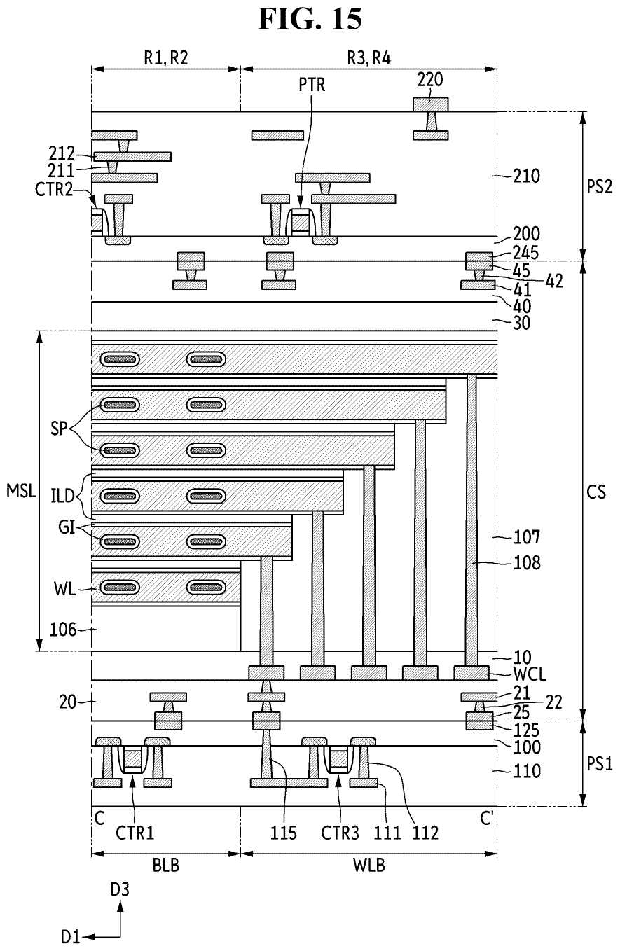

Unlike illustrated, as illustrated in FIG. 8 or 15, the first peripheral circuit structure PS1 and the cell structure CS may be electrically connected through the first bonding pad 125 and the lower bonding pad 25, and the second peripheral circuit structure PS2 and the cell structure CS may be electrically connected through the second bonding pad 245 and the upper bonding pad 45.

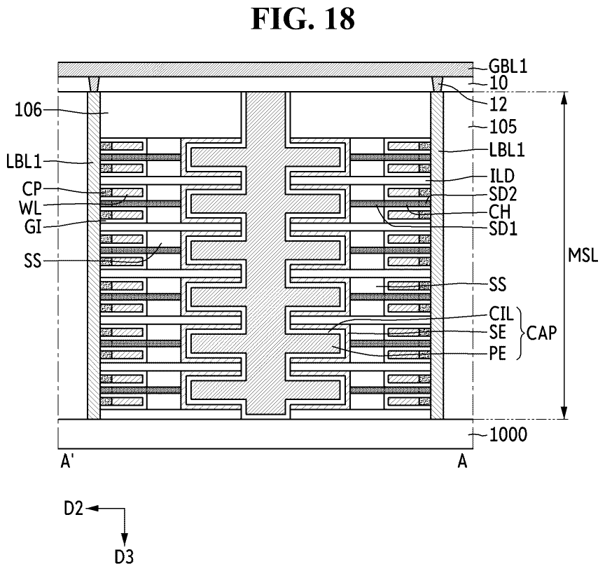

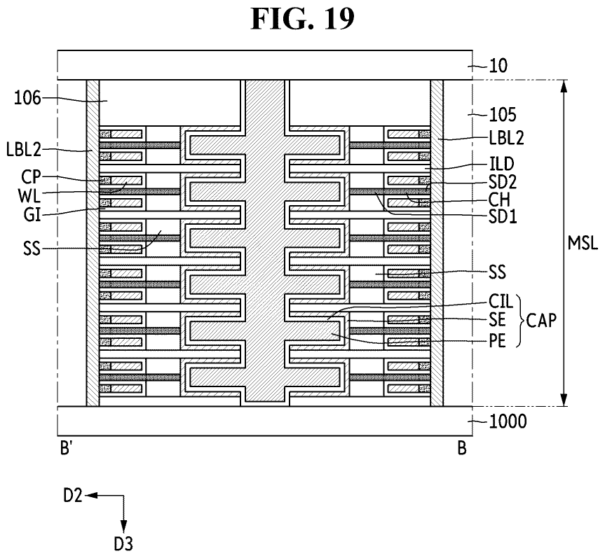

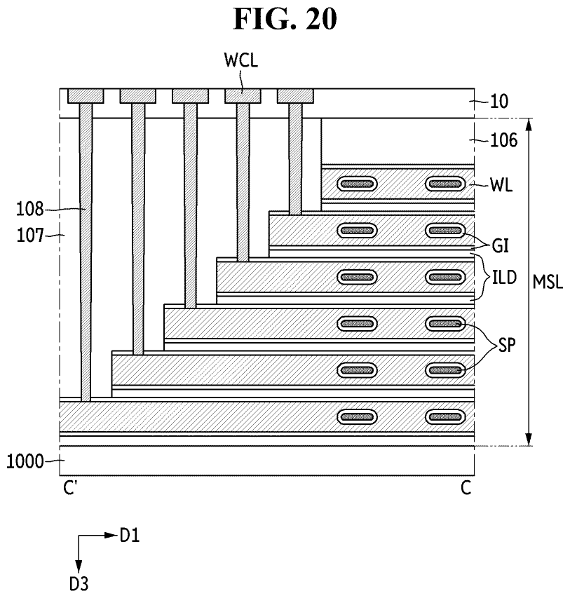

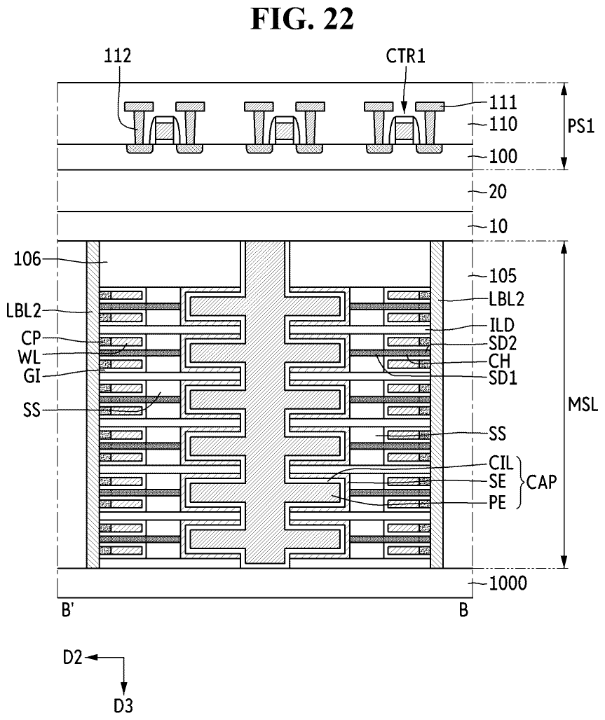

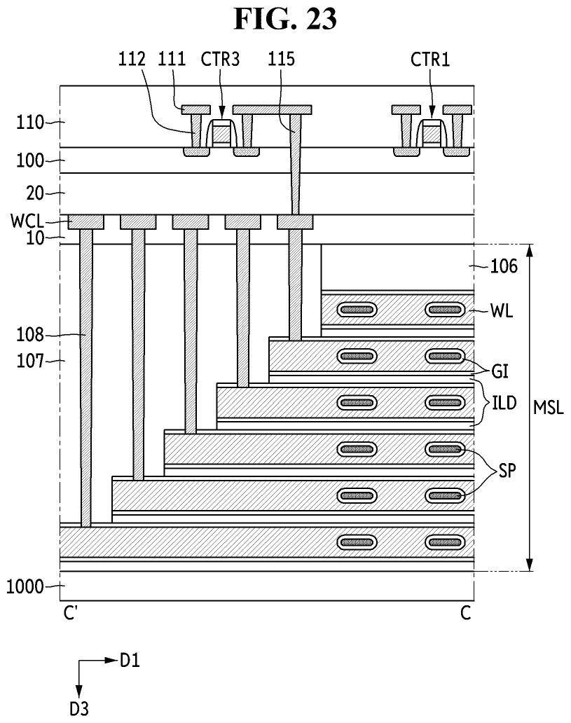

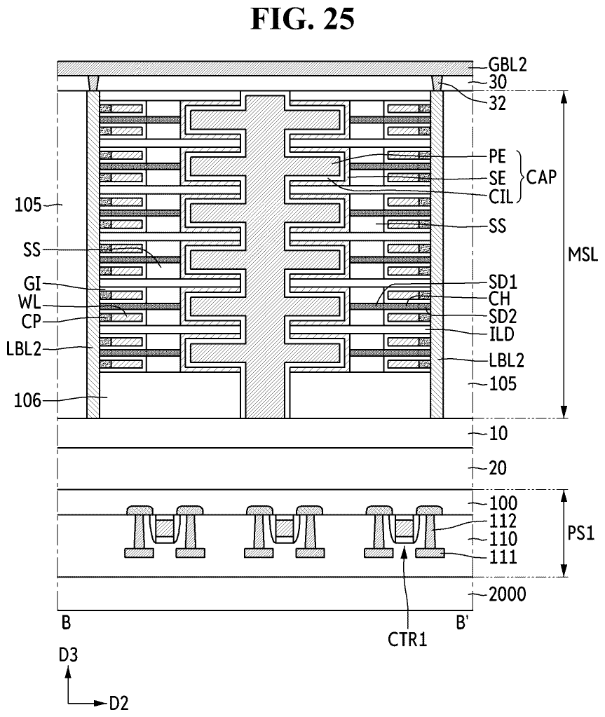

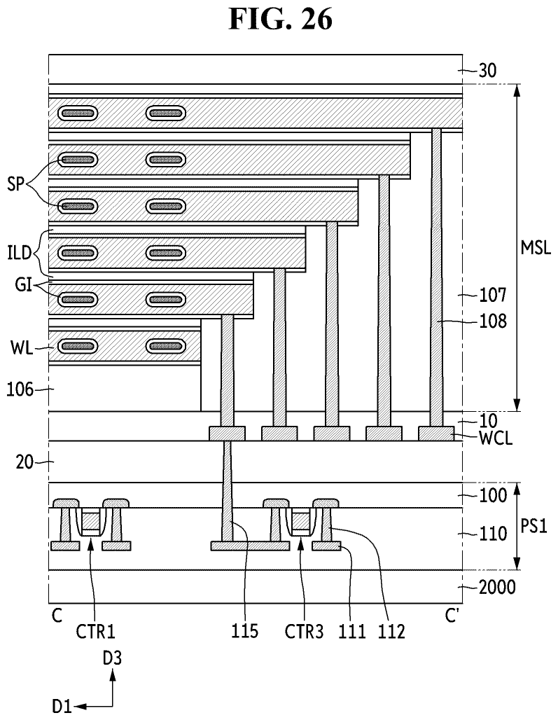

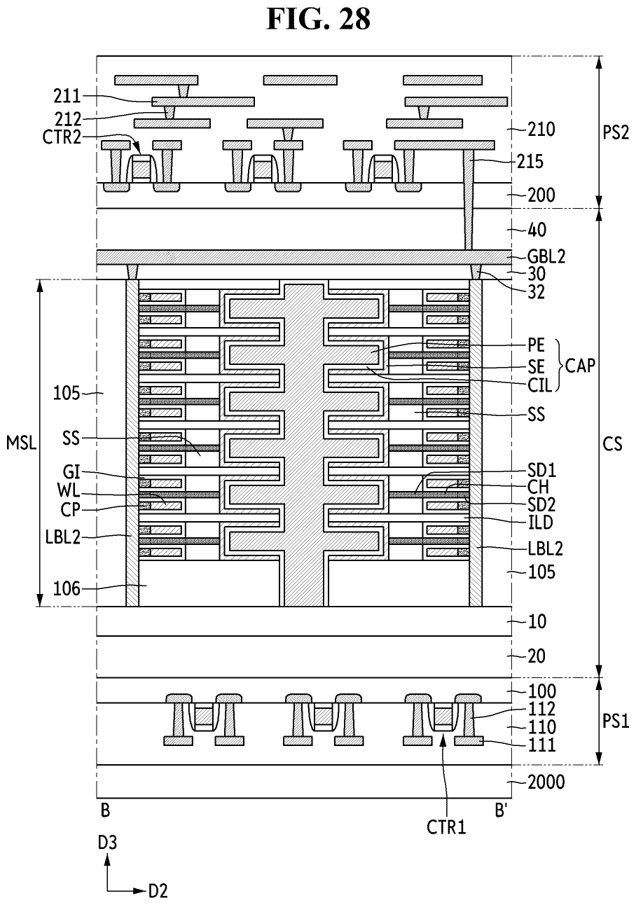

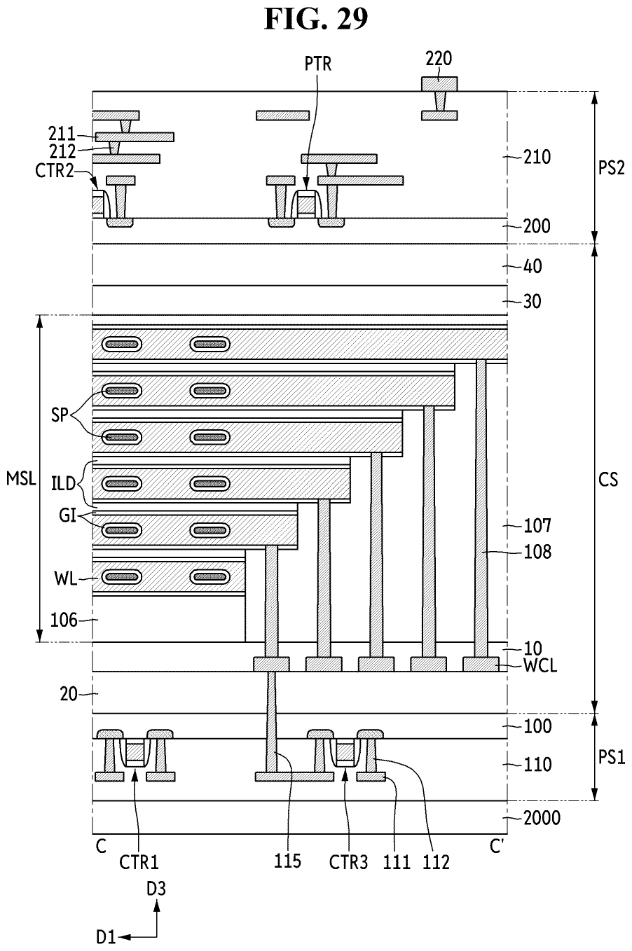

FIGS. 18 to 29 are views for describing a method for manufacturing a semiconductor memory device according to some exemplary embodiments. For convenience of explanation, points different from those described with reference to FIGS. 1 to 17 will be mainly described.

Referring to FIGS. 18 to 20, a memory cell layer MSL may be formed on a substrate 1000. The memory cell layer MSL may include interlayer insulating patterns ILD, semiconductor patterns SP, word lines WL, a gate insulating film GI, a capping insulating pattern CP, a spacer insulating pattern SS, first and second separation insulating patterns STI1 and STI2, a buried insulating pattern 105, a data storage element CAP, and first and second cell insulating layers 106 and 107.

Next, a first lower insulating layer 10, a first bit line contact 12, a first global bit line GBL1, a word line contact 108, and a connection line WCL may be formed on the memory cell layer MSL. The first bit line contact 12 may be formed on the first local bit line LBL1. The first global bit line GBL1 may be formed on the first bit line contact 12. Each word line contact 108 may be formed on each word line WL. A connection line WCL may be formed on the word line contact 108.

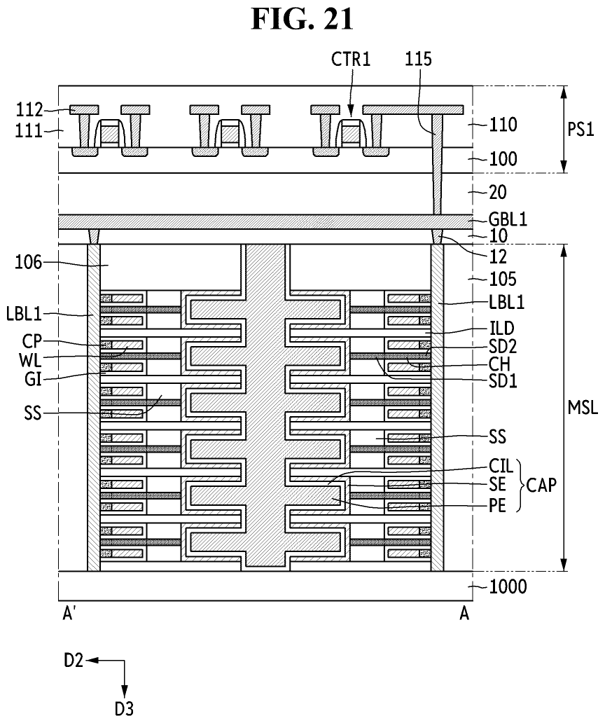

Referring to FIGS. 21 to 23, a second lower insulating layer 20 may be formed on the first lower insulating layer 10. A first peripheral circuit structure PS1 may be formed on the second lower insulating layer 20. The first peripheral circuit structure PS1 may be bonded to the memory cell layer MSL. For example, the first peripheral circuit structure PS1 may be connected to the first global bit line GBL1 through the first connection via 115 and may be connected to the connection line WCL.

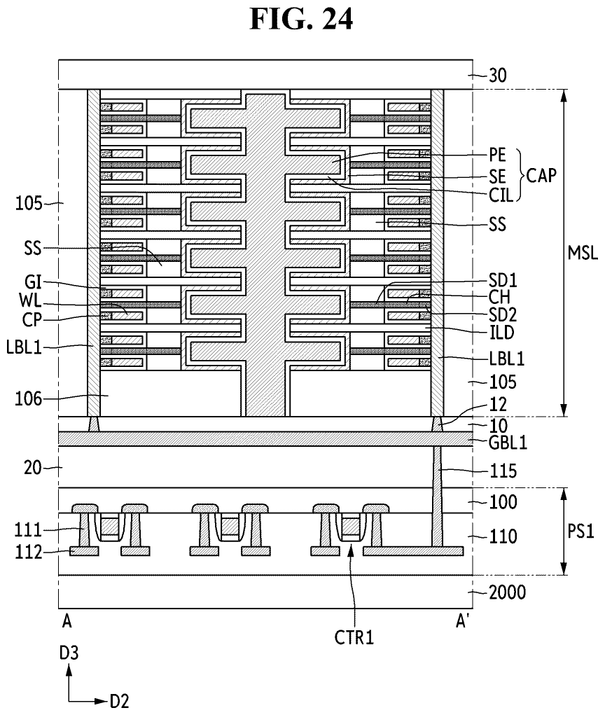

Referring to FIGS. 24 to 26, a carrier substrate 2000 may be attached on the first insulating layer 110. Next, the carrier substrate 2000, the first peripheral circuit structure PS1, the second lower insulating layer 20, the first lower insulating layer 10, the memory cell layer MSL, and the substrate 1000 may be inverted in a vertical direction. For example, the carrier substrate 2000 may be positioned at the lowest portion.

Next, the substrate 1000 may be removed. Accordingly, an upper surface of the memory cell layer MSL may be exposed.

Next, a first upper insulating layer 30, a second bit line contact 32, and a second global bit line GBL2 may be formed on the memory cell layer MSL. The second bit line contact 32 may be formed on the second local bit line LBL2. The second global bit line GBL2 may be formed on the second bit line contact 32.

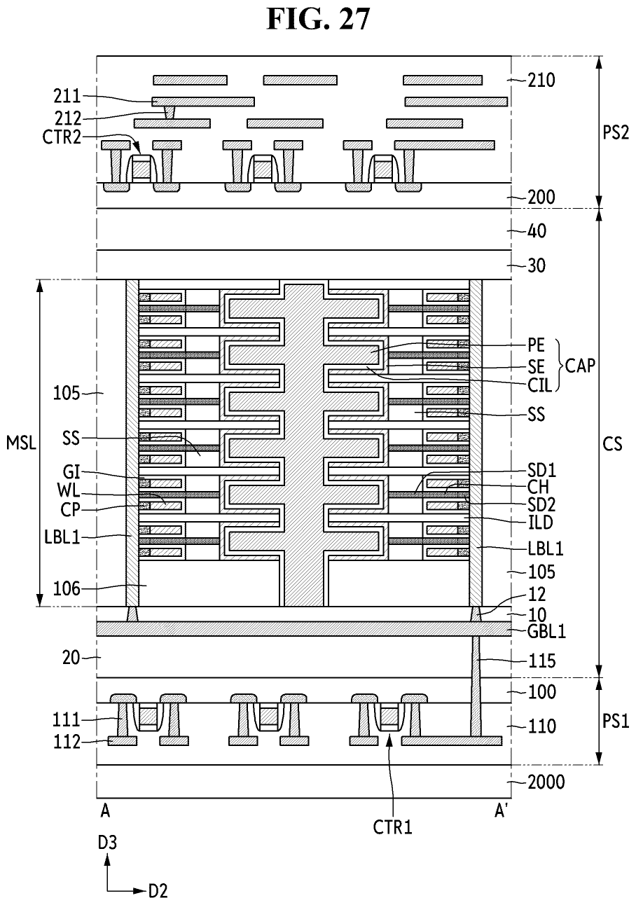

Referring to FIGS. 27 to 29, a second upper insulating layer 40 may be formed on the first upper insulating layer 30. A second peripheral circuit structure PS2 may be formed on the second upper insulating layer 40. The second peripheral circuit structure PS2 may be bonded to the memory cell layer MSL. For example, the second peripheral circuit structure PS2 may be connected to the second global bit line GBL2 through the second connection via 215.

Next, referring to FIGS. 10 to 12, the carrier substrate 2000 may be removed.

The exemplary embodiments of the present disclosure have been described above with reference to the accompanying drawings, but the present disclosure may be implemented in various different forms, and those skilled in the art to which the present disclosure pertains may understand that the present disclosure may be implemented in other specific forms without changing the technical spirit or essential features of the present disclosure. Therefore, it should be understood that the exemplary embodiments described above are illustrative in all aspects and not restrictive.

1. A semiconductor memory device comprising:
a three-dimensional memory cell array including memory cells including cell transistors arranged in a three-dimensional array and corresponding data storage elements arranged in a three-dimensional array;
a plurality of word lines extending lengthwise in a first horizontal direction, and spaced apart from each other in a vertical direction and a second horizontal direction crossing the first horizontal direction;
each cell transistor including a semiconductor pattern extending lengthwise in the second horizontal direction and having a first end connected to a respective data storage element, each semiconductor pattern intersecting a word line of the plurality of word lines;
first local bit lines crossing the word lines and second local bit lines crossing the word lines, each bit line of the first local bit lines and second local bit lines extending lengthwise in the vertical direction;
first global bit lines extending lengthwise in the second horizontal direction and electrically connected to the first local bit lines, below the word lines; and
second global bit lines extending lengthwise in the second horizontal direction and electrically connected to the second local bit lines, above the word lines.

2. The semiconductor memory device of claim 1, wherein:
each first global bit line electrically connected to first local bit lines electrically connects a group of first local bit lines arranged in the second horizontal direction;
each second global bit line electrically connected to second local bit lines electrically connects a group of second local bit lines arranged in the second horizontal direction; and
when viewed in a plan view, the first global bit lines and second global bit lines are alternatingly arranged along the first horizontal direction.

3. The semiconductor memory device of claim 2, wherein:
each semiconductor pattern has a second end connected to a local bit line from among the first local bit lines and the second local bit lines.

4. The semiconductor memory device of claim 3, wherein the data storage elements are storage capacitors.

5. The semiconductor memory device of claim 3, further comprising:
a first peripheral circuit below the first global bit lines, electrically connected to the first global bit lines, and including transistors for controlling a first group of the memory cells; and
a second peripheral circuit above the second global bit lines, electrically connected to the second global bit lines, and including transistors for controlling a second group of the memory cells.

6. The semiconductor memory device of claim 2, wherein:
each word line surrounds a plurality of semiconductor patterns arranged along the first horizontal direction.

7-14. (canceled)

15. A semiconductor memory device comprising:
a first peripheral circuit structure including a first semiconductor layer and first transistors of the first semiconductor layer;
a memory cell structure on the first peripheral circuit structure and including word lines extending lengthwise in a first horizontal direction and spaced apart from each other in a vertical direction and bit lines extending lengthwise in the vertical direction and spaced apart from each other in the first horizontal direction; and
a second peripheral circuit structure on the memory cell structure so that the memory cell structure is between the first peripheral circuit structure and the second peripheral circuit structure, the second peripheral circuit structure including a second semiconductor layer and second transistors of the second semiconductor layer,
wherein the bit lines include first local bit lines and second local bit lines,
the first local bit lines are electrically connected to the first transistors, and
the second local bit lines are electrically connected to the second transistors.

16. The semiconductor memory device of claim 15, wherein the first local bit lines and the second local bit lines are arranged alternately along the first horizontal direction,
the first transistors constitute a first sense amplifier, and
the second transistors constitute a second sense amplifier.

17. The semiconductor memory device of claim 15, wherein:
the memory cell structure further includes semiconductor patterns extending lengthwise in a second horizontal direction and spaced apart from each other in the vertical direction, each including a first end and a second end, and respective data storage elements connected to the second ends of the semiconductor patterns, and
the bit lines are connected to the first end of the semiconductor patterns.

18. The semiconductor memory device of claim 15, wherein the first peripheral circuit structure further includes third transistors on the first semiconductor layer, and
the word lines are electrically connected to the third transistors.

19. The semiconductor memory device of claim 18, wherein:
the memory cell structure includes a bit line connection region and a word line connection region,
the word lines have a step structure in the word line connection region,
the first peripheral circuit structure includes a first region in which the first transistors are disposed, and a second region in which the third transistors are disposed,
the first region overlaps the bit line connection region in the vertical direction, and
the second region overlaps the word line connection region in the vertical direction.

20. The semiconductor memory device of claim 15, wherein:
the first peripheral circuit structure further includes third transistors on the first semiconductor layer, and
the second peripheral circuit structure further includes fourth transistors on the second semiconductor layer,
the word lines include first word lines and second word lines,
the first word lines are electrically connected to the third transistors, and
the second word lines are electrically connected to the fourth transistors.

21. The semiconductor memory device of claim 20, wherein the first word lines are disposed between the first peripheral circuit structure and the second word lines.

22. The semiconductor memory device of claim 20, wherein the memory cell structure includes a bit line connection region and a word line connection region,
the word lines have a step structure in the word line connection region,
the first peripheral circuit structure includes a first region in which the first transistors are disposed, and a second region in which the third transistors are disposed,
the second peripheral circuit structure includes a third region in which the second transistors are disposed, and a fourth region in which the fourth transistors are disposed,
the first region and the third region overlap the bit line connection region in the vertical direction, and
the second region and the fourth region overlap the word line connection region in the vertical direction.

23. A semiconductor memory device comprising:
a first peripheral circuit structure including a first semiconductor layer, first operational transistors on the first semiconductor layer, and a first conductive pattern electrically connected to the first operational transistors;
a cell structure on the first peripheral circuit structure and including word lines extending lengthwise in a first horizontal direction and spaced apart from each other in a vertical direction, first and second local bit lines extending lengthwise in the vertical direction and spaced apart from each other in the first horizontal direction, first global bit lines below the word lines, and second global bit lines above the word lines; and
a second peripheral circuit structure on the cell structure so that the cell structure is between the first peripheral circuit structure and the second peripheral circuit structure, the second peripheral circuit structure including a second semiconductor layer, second operational transistors on the second semiconductor layer, and a second conductive pattern electrically connected to the second operational transistors;
wherein the first local bit lines and the second local bit lines are disposed alternately along the first horizontal direction,
wherein the first local bit lines are electrically connected to the first operational transistors through the first global bit lines and the first conductive pattern, and
wherein the second local bit lines are electrically connected to the second operational transistors through the second global bit lines and the second conductive pattern.

24. The semiconductor memory device of claim 23, wherein:
the cell structure further includes a lower bonding pad on each of the first global bit lines, and an upper bonding pad on each of the second global bit lines,
the first peripheral circuit structure further includes first bonding pads on the first conductive pattern,
the second peripheral circuit structure further includes second bonding pads on the second conductive pattern,
the first bonding pads contact the lower bonding pads, respectively, and
the second bonding pads contact the upper bonding pads, respectively.

25. The semiconductor memory device of claim 23, further comprising a first connection via connecting each of the first global bit lines and the first conductive pattern, and a second connection via connecting a respective second global bit line and the second conductive pattern.

26. The semiconductor memory device of claim 23, wherein the first semiconductor layer and the second semiconductor layer each include at least one of a semiconductor substrate, an oxide semiconductor, and a two-dimensional material.

27. The semiconductor memory device of claim 23, wherein:
the cell structure further includes first connection lines below the word lines,
the first peripheral circuit structure further includes third operational transistors on the first semiconductor layer, and
the word lines are electrically connected to the third operational transistors through the first connection lines and the first conductive pattern.

28. The semiconductor memory device of claim 23, wherein:
the cell structure further includes first connection lines below the word lines and second connection lines above the word lines,
the first peripheral circuit structure further includes third operational transistors on the first semiconductor layer,
the second peripheral circuit structure further includes fourth operational transistors on the second semiconductor layer,
the word lines include first word lines and second word lines,
the first word lines are electrically connected to the third operational transistors through the first connection lines and the first conductive pattern, and
the second word lines are electrically connected to the fourth operational transistors through the second connection lines and the second conductive pattern.
